(19) United States
(12) Patent Application Publication
(10) Pub. No.: US 2013/0087180 A1
(43) Pub. Date: Apr. 11, 2013

(54) WEARABLE THERMOELECTRIC GENERATOR SYSTEM

(71) Applicant: PERPETUA POWER SOURCE TECHNOLOGIES, INC., Corvallis, OR (US)

(72) Inventors: Ingo Stark, Corvallis, OR (US); Paul H. McClelland, Monmouth, OR (US); Marcus S. Ward, Salem, OR (US); Leif E. Schneider, Albany, OR (US)

(73) Assignee: PERPETUA POWER SOURCE TECHNOLOGIES, INC., Corvallis, OR (US)

(21) Appl. No.: 13/648,277

(22) Filed: Oct. 9, 2012

Related U.S. Application Data
(60) Provisional application No. 61/545,492, filed on Oct. 10, 2011.

(51) Int. Cl. H01L 35/30

(52) U.S. Cl. 136/205

(57) ABSTRACT

A wearable thermoelectric generator system thermoelectric generator may include a thermoelectric generator, a heat collector, and a heat exchanger. The heat collector may be configured to be placed in contact with a skin surface of a wearer. The heat exchanger may be configured to be exposed to ambient air. The thermoelectric generator may be mounted between the heat collector and the heat exchanger. The thermoelectric generator may be electrically connected to a load. The load may be packaged separately from the thermoelectric generator.

### CROSS-REFERENCE TO RELATED APPLICATIONS

The present application claims priority to pending U.S. Provisional Application No. 61/545,492 filed on Oct. 10, 2011, and entitled WEARABLE THERMOELECTRIC GENERATOR SYSTEM, the entire contents of which is expressly incorporated herein by reference.

### FIELD

The present disclosure pertains generally to thermoelectric devices and, more particularly, to a thermoelectric generator system configured in a wearable package and providing efficient conversion of body heat into useable electricity.

### BACKGROUND

The increasing trend toward miniaturization of microelectronic devices has driven the development of miniaturized power supplies. Batteries and solar cells are traditional power sources for such microelectronic devices. However, the power that is supplied by batteries dissipates over time requiring that the batteries be periodically replaced. Solar cells, although having an effectively unlimited useful life, may only provide a transient source of power as sunlight or light from other sources may not always be available. Furthermore, solar cells require periodic cleaning of their exterior surfaces in order to maintain efficiency of energy conversion.

Thermoelectric generators are self-sufficient energy sources that convert thermal energy into electrical energy under established physics principles. The Seebeck effect is a phenomenon whereby heat differences may be converted into electricity due in large part to charge carrier diffusion in a conductor. Electrical power may be generated under the Seebeck effect by utilizing thermocouples which are each comprised of a pair of dissimilar metals (n-type and p-type) joined at one end. N-type and p-type, respectively, refers to the negative and positive types of charge carriers within the material.

The temperature gradient that exists between the ends of the thermocouple may be artificially applied or the temperature gradient may be natural, occurring as waste heat such as heat that is constantly rejected by the human body. In a wristwatch, one side is exposed to air at ambient temperature while the opposite side is exposed to the higher temperature of the wearer's skin. Thus, a small temperature gradient is typically present across the thickness of the wristwatch. In this same regard, a thermoelectric generator may be placed in contact with a person's skin to take advantage of the temperature gradient and generate a supply of power to operate an electronic device, sensor, or to be used for other purposes. Advantageously, many microelectronic devices require only a small amount of power and are therefore compatible for powering by a thermoelectric generator.

The core of the human body is generally maintained at a relatively constant temperature due to the layers of muscle, fat, and skin that surround the core and provide a relatively high thermal resistance. However, the temperature of the outer skin may fluctuate due to thermoregulation of the core of the body. In this regard, the temperature of the skin may vary depending upon the thermal resistance at the skin surface and on the temperature of the environment such as the ambient air temperature. The variation in temperature of the skin may result in variations in heat flow across a thermoelectric generator that is in contact with the skin. The variation in heat flow affects the electricity-producing capabilities of the thermoelectric generator.

More specifically, in order to generate maximum power by a thermoelectric generator, heat flow through the thermoelectric generator must generally be maximized. Similar to electrical impedance matching to maximize electrical power transfer, maximizing heat flow through a thermoelectric generator requires matching the thermal resistance of the thermoelectric generator to the thermal resistance of the environment. For a thermoelectric generator that is in contact with the skin of a human body, the thermal resistance of the thermoelectric generator must be relatively high in order to match the relatively high thermal resistance of the human body.

As can be seen, there exists a need in the art for a system and method for optimizing the thermal resistance matching of a thermoelectric generator with the environment such that power output of the thermoelectric generator is maximized.

### SUMMARY

The present disclosure specifically addresses and alleviates the above referenced deficiencies associated with thermoelectric generators. The disclosure provides a wearable thermoelectric generator system having at least one thermoelectric generator (TEG) and including one or more features and/or means for optimizing the matching of the thermal resistance of the TEG with the thermal resistance of an environment to which the TEG may be exposed.

The environment may include at least one of a heat source, a heat sink, and/or one or more components of the wearable thermoelectric generator system. For example, the wearable thermoelectric generator system may include an inner material layer configured to be exposed to the heat source, and an outer material layer configured to be exposed to the heat sink. The TEG may include a heat couple plate configured to be placed in contact with the thermocouple and the inner material layer, and a heat couple plate configured to be placed in contact with the thermocouple and the outer material layer. The heat couple plates may form part of the thermoelectrically inactive zone of the TEG.

Each one of the components of the environment has a thermal resistance. The wearable thermoelectric generator system may be configurable such that the thermal resistance of the thermoelectrically active zone is substantially equivalent to the sum of the thermal resistances in series of the heat sink, the heat source, and the components of the wearable thermoelectric generator system

In an embodiment, the wearable thermoelectric generator system disclosed herein may include at least one thermoelectric generator. The TEG may have an in-plane configuration and/or a cross-plane configuration. For an in-plane configuration, the TEG may include a bottom plate, a top plate, and a foil assembly comprising either a single, elongate foil segment or a series of foil segments that are joined end-to-end using connectors straddling each end-to-end joint. Adhesive may be utilized to bond the connector to at least one of the front and back substrate surfaces of the end-to-end foil segments in order to mechanically connect the foil segments. More specifically, the connector may be bonded to at least the front substrate surface. However, for a stronger mechanical connection, a connector may also be bonded to the back substrate surface. Electrically adhesive having a relatively high electrical conductivity may be applied at top and bottom edges of the connector to electrically connect the foil segments. However, the connectors may optionally include metal contacts deposited adjacent top and bottom edges of the connector to enhance the electrical conductivity between the foil segments.

The metal contact is configured to electrically connect an endmost one of the n-type thermoelectric legs of one of the foil segments to an endmost one of the p-type thermoelectric legs of an adjacent one of the foil segments. In this manner, each one of the p-type thermoelectric legs is electrically connected to adjacent ones of the n-type thermoelectric legs at opposite ends of the p-type thermoelectric legs such that the n-type and p-type thermoelectric legs are electrically connected in series and thermally connected in parallel

The foil assembly and/or foil segments are interposed between the bottom plate and the top plate in a spirally wound arrangement. The foil assembly is perpendicularly disposed between and in thermal contact with the bottom and top plates. A series of alternating n-type and p-type thermoelectric legs is disposed on a substrate of each one of the foil segments that make up the foil assembly in one embodiment of the thermoelectric generator. In another embodiment, the n-type and p-type thermoelectric legs are disposed on a single, elongate substrate of a single foil segment. The thermoelectric legs are generally fabricated from a bismuth telluride-type thermoelectric material.

The top plate is disposed in spaced relation above the bottom plate. The bottom and top plates may have a generally circular configuration and may be fabricated from any rigid material capable of suitable thermal conductance. In this regard, the top and bottom plate may be fabricated from ceramic material, metal material or any other suitable material or combination thereof. The bottom plate and top plate are configured to provide thermal contact between a heat sink and a heat source such that a temperature gradient may be developed across the alternating n-type and p-type thermoelectric legs.

Each one of the foil segments has a front substrate surface and a back substrate surface which opposes the front substrate surface. The spaced, alternating n-type and p-type thermoelectric legs are disposed in parallel arrangement to each other on the front substrate surface. Each of the n-type and p-type thermoelectric legs are formed of the thermoelectric material generally having a thickness in the range of from about 10 microns (μm) to about 100 μm with a generally thicker configuration being preferred due a correspondingly greater cross-sectional area providing concomitantly greater electrical current therethrough. The front substrate surface may have a surface roughness that is smoother than that of the back substrate surface in order to enhance the repeatability of forming the n-type and p-type thermoelectric legs on the front substrate surface. However, the back substrate surface may have the thermoelectric legs disposed thereupon and may be appropriately pre-treated prior to the deposition process.

Each one of the p-type and n-type thermoelectric leg pairs makes up a thermocouple of the thermoelectric generator. The width of the thermoelectric legs may be in the range of from about 10 μm to about 100 μm, the length thereof being in the range of from about 100 μm to about 500 μm. A preferred length of the n-type and p-type thermoelectric legs is about 500 μm. A preferred width of the n-type thermoelectric leg is about 60 μm while a preferred width of the p-type thermoelectric leg is about 40 μm. The geometry of the respective n-type and p-type thermoelectric legs may be adjusted to a certain extent depending on differences in electrical conductivities of each n-type and p-type thermoelectric leg.

Each one of the p-type thermoelectric legs is electrically connected to adjacent n-type thermoelectric legs at opposite ends of the p-type thermoelectric legs by a hot side metal bridge and a cold side metal bridge such that electrical current may flow through the thermoelectric legs from a bottom to a top of a p-type thermoelectric leg, or vice versa. The plurality of foil segments may preferably include a total of about 5000 thermocouples connected together and substantially evenly distributed on the array of foil segments and forming a thermocouple chain. However, any number of thermocouples may be provided in the thermoelectric generator.

Each of the thermocouples includes one n-type and one p-type thermoelectric leg. Thus, a thermoelectric generator having a chain of 5000 thermocouples will include 5000 n-type thermoelectric legs and 5000 p-type thermoelectric legs. The thermoelectric generator may preferably include any number of foil segments connected end-to-end to form the foil assembly. The foil assembly is thereafter spirally wound such that the front and back substrate surfaces of adjacently disposed wraps of the foil assembly are disposed in overlapping, but electrically non-conductive, contact with one another. A cover layer may be provided on at least one of the front and back substrate surfaces to prevent electrical conductance between the wraps of the foil assembly. The thermocouple chain may be connected to the top and bottom plates which, in turn, may be connected to an external load.

Each one of the hot side metal bridges and cold side metal bridges is configured to electrically connect an n-type thermoelectric leg to a p-type thermoelectric leg. Each one of the hot side and cold side metal bridges is also configured to act as a diffusion barrier in order to impede the diffusion of unwanted elements into the n-type and p-type thermoelectric legs which may be easily contaminated with foreign material. Additionally, each one of the hot side and cold side metal bridges is configured to impede the diffusion of unwanted elements out of the n-type and p-type thermoelectric legs. Finally, each one of the hot side and cold side metal bridges is configured to optimally conduct heat into and out of the p-type and n-type thermoelectric legs. In this regard, the hot side and cold side metal bridges may be fabricated of a highly thermally conductive material such as gold-plated nickel.

The substrate of each foil segment may have a thickness in the range of from about 7.5 μm to about 50 μm, although the thickness of the substrate is preferably about 25 μm. Because of the desire to reduce the thermal heat flux through the substrate in order to increase the efficiency of energy conversion, it is desirable to decrease the thickness of the substrate upon which the thermoelectric legs are disposed. An electrically insulating material with a low thermal conductivity such as polyimide film may be utilized for the substrate.

The thermoelectric film that makes up the n-type and p-type thermoelectric legs may be comprised of a semiconductor compound of the bismuth telluride (Bi₂Te₃) type. However, specific compositions of the semiconductor compound may be altered to enhance the thermoelectric performance of the n-type and p-type thermoelectric legs. Specifically, the composition of the n-type thermoelectric legs may include the elements Bismuth (Bi), Tellurium (Te) and Selenium (Se). The composition of the p-type thermoelectric legs may include the elements Bismuth (Bi), Antimony (Sb) and Tellurium (Te). Furthermore, excess of the elements Tellurium (Te) and Selenium (Se) may be provided in n-type material. Excess of the element Tellurium (Te) may be provided in p-type material. The amounts of excess of each of these elements may be altered in order to enhance the fabrication and power characteristics thereof.

In the method for producing the foil segment for the thermoelectric generator, magnetron sputtering may be utilized for deposition of a relatively thick “bismuth telluride type” thermoelectric material film onto the substrate. It should be noted that as known in the art, bismuth telluride refers to a specific material system and is referred to as such because the p-type and n-type materials are from the same bismuth telluride type. Due to a unique sputtering target composition, the sputtering regime, and post-annealing process, relatively high values for the power factor (P) of the thermoelectric material are achievable. For example, in one embodiment of the thermoelectric generator, an average value for the power factor (Pₚ) of p-type Bi₂Te₃-type thermoelectric material at room temperature is about 45 μW/(K²*cm) while an average value for the power factor (Pₙ) for n-type Bi₂Te₃-type thermoelectric material at room temperature is about 45 μW/(K²* cm).

Also disclosed herein is a thermoelectric generator having an in-plane configuration and including thermoelectric legs arranged in rows on a substrate and oriented in non-parallel relation to the row axis such that the thermoelectric legs form a meandering pattern on the substrate. The thermoelectric legs and substrate comprise a foil assembly which is sandwiched between a pair of thermally conductive heat couple plates (i.e., top and bottom plates). The foil substrate is relatively thin which minimizes internal stresses in the thermoelectric legs due to the ability of the thin foil substrate to bend and flex in response to such internal stresses as compared to a relatively stiff and rigid silicon wafer which lacks the necessary flexibility to accommodate or bend in response to internal stresses in the thermoelectric legs.

Advantageously, the meandering pattern of the thermoelectric legs also provides a means for minimizing internal stresses in thin films formed on the substrate such as metal bridges and thermoelectric legs. Such internal stresses may otherwise develop as a result of differences in the coefficient of thermal expansion of the substrate relative to the coefficient of thermal expansion of the thin films during the fabrication process. In this regard, the meandering pattern of the thermoelectric legs provides for a large number of changes in the lateral orientation of the legs within a relatively short distance along the substrate. The large number of orientation changes improves the mechanical stability of the thermoelectric legs that make up the thermocouples of the thermoelectric generator. In addition, the meandering pattern of thermoelectric legs provides a means for minimizing the length of the thermoelectric legs which further increases the mechanical stability and reliability of the thermocouples.

In an embodiment, the thermoelectric generator comprises the pair of top and bottom plates having the foil assembly interposed therebetween. The substrate of the foil assembly may comprise an electrically insulating material having a relatively low thermal conductivity. The thermoelectric legs may be formed of thermoelectric material such as semiconductor material and/or metallic material. The thermoelectric legs are arranged on the substrate as a series of legs formed of alternating dissimilar materials. For example, the thermoelectric legs may be arranged on the substrate in a pattern of alternating n-type and p-type legs formed, respectively, of n-type and p-type semiconductor materials. Alternatively, the thermoelectric legs may be arranged on the substrate in a pattern of metal legs alternating with semiconductor legs formed of one type of semiconductor material (e.g., n-type or p-type). The thermoelectric legs may be arranged in one or more rows and may be formed on one or both of the upper and lower surfaces of the substrate.

Each one of the thermoelectric legs defines a leg axis which is preferably oriented in non-parallel relation to the row axis. The thermoelectric generator may further include at least one pair of thermally conductive strips which may be positioned on opposite sides of the substrate. The thermally conductive strips may be aligned with opposite ends of the thermoelectric legs in the row such that one end of the thermoelectric legs is in thermal contact with the top plate and the opposite end of the thermoelectric legs is in thermal contact with the bottom plate. Furthermore, the thermally conductive strips define thermal gaps between the thermoelectric legs and the top and bottom plates.

The thermal gaps define areas of increased thermal resistance relative to the low thermal resistance provided by the thermally conductive strips. The thermal gaps may be filled with a gas such as, without limitation, air, nitrogen, krypton and xenon or any other suitable fluid or solid of low thermal conductivity. The thermal gaps cause heat to flow lengthwise through the thermoelectric legs. In the arrangement of the in-plane thermoelectric generator, heat flows lengthwise through the thermoelectric legs in order to produce a voltage potential across the thermoelectric legs. The generated electric current flows through the legs along a direction that is parallel to the plane of the substrate and parallel to the leg axis of each one of the thermoelectric legs. Advantageously, the relatively simple construction of the foil assembly and the means for interconnection of the foil assembly to the top and bottom heat couple plates facilitates mass-production of the thermoelectric generator in a cost-effective manner.

The features, functions and advantages that have been discussed can be achieved independently in various embodiments of the present disclosure or may be combined in yet other embodiments, further details of which can be seen with reference to the following description and drawings below.

### BRIEF DESCRIPTION OF THE DRAWINGS

These as well as other features of the present disclosure will become more apparent upon reference to the drawings wherein:

FIG. 1 is an illustration of a wearable thermoelectric generator system having at least one thermoelectric generator (TEG) and shown being worn as an armband on an arm of a person;

FIG. 2 is a cross sectional view of the system taken along line 2 of FIG. 1;

FIG. 3 is a schematic illustration of a thermocouple of the TEG and an environment to which the TEG may be exposed and illustrating an active zone and a pair of inactive zones of the thermocouple;

FIG. 4 is a chart listing a component associated with the system and a letter code representing a thermal resistance from the corresponding component;

FIG. 5 is a plot of power output of a TEG as a function of the thermal matching of the active zone of a thermocouple with the inactive zones of the thermocouple as may be included in a TEG of the system disclosed herein;

FIG. 6 is a cross sectional view of the system in a chest band embodiment;

FIG. 7a is a cross sectional view of the system in a wrist band embodiment;

FIG. 7b is a perspective view of the system in a further wrist band embodiment;

FIG. 8 is a plan view of the system in a back pack embodiment;

FIG. 8a is a cross sectional view of the system illustrating an arrangement for integrating a TEG into the system;

FIG. 8b is a cross sectional view of the system illustrating an additional arrangement for integrating a TEG into the system;

FIG. 9 are perspective views of the TEG in various disc-shaped embodiments;

FIG. 10 is an embodiment of a block diagram illustrating management electronics for regulating the operation of the system;

FIG. 11 is a perspective view of a thermoelectric generator illustrating the arrangement of a plurality of foil segments;

FIG. 12 is a cross-sectional side view of the thermoelectric generator taken along line 12 of FIG. 11 illustrating the arrangement of alternating n-type and p-type thermoelectric legs disposed on a substrate film of each of the foil segments;

FIG. 13 is a schematic illustration of p-type and n-type thermoelectric leg pair that makes up a thermocouple of the thermoelectric generator;

FIG. 14a is a cross-sectional view of a round shaped thermoelectric generator in an alternative embodiment and illustrating a spirally-wound foil assembly captured between a top plate and a bottom plate and illustrating filler material disposed within a central hollow core of the foil assembly;

FIG. 14b is a top view of the thermoelectric generator of FIG. 14a and illustrating the circular shape of the top plate;

FIG. 15a is a cross-sectional view of the thermoelectric generator and illustrating a bore formed in the top plate and extending into the filler in the otherwise hollow core such as may be used for encapsulating electronic circuitry within the thermoelectric generator;

FIG. 15b is a top view of the thermoelectric generator shown in FIG. 15a and illustrating the centrally located bore formed in the top plate;

FIG. 16a is a side view of the foil assembly comprised of a pair of foil segments disposed in end to end contact and illustrating the configuration of end contacts adjacent free ends at top and bottom edges of each of the adjacently disposed foil segments as may be used for electrically connecting an endmost pair of n-type and p-type thermoelectric legs of one of the foil segments to an endmost of n-type and p-type thermoelectric legs of the adjacent one of the foil segments;

FIG. 16b is a plan view of a connector as may be utilized on at least one of the front and back substrate surfaces for splicing together adjacently disposed foil segments;

FIG. 16c is a plan view of an improved configuration of a connector having metal contacts disposed at top and bottom edges of the connector for improvement of the electrical connection between adjacently-disposed foil segments;

FIG. 16d is a side view of an adjacently disposed pair of foil segments and indicating a layer of assembly adhesive disposed approximately midway between the top and bottom edges of each of the foil segments and electrical adhesive disposed on respective ones of the end contacts of the adjacently disposed foil segments;

FIG. 16e is a side view of an opposite surface of the foil assembly from that which is shown in FIG. 6d and illustrating a layer of assembly adhesive disposed thereon for mechanically connecting the adjacently disposed foil segments with the connector (not shown);

FIG. 17a is a side view of a pair of the foil segments disposed end-to-end with a “single” electrical connection between an endmost one of the end type thermoelectric legs of one of the foil segments to an endmost one of the p-type thermoelectric legs of the adjacent one of the foil segments;

FIG. 17b is a side view of the foil segments shown in FIG. 17a and illustrating the location of the assembly adhesive and the electrical adhesive as may be used for mechanically and electrically adjoining the foil segments;

FIGS. 18a-18f are plots illustrating the power characteristics of the thermoelectric generator at varying temperature differentials between the top and bottom plates;

FIG. 19 is a perspective illustration of a thermoelectric generator having an in-plane configuration;

FIG. 20 is a perspective exploded illustration of an embodiment of the thermoelectric generator comprising a foil assembly sandwiched between a top plate and a bottom plate and wherein the foil assembly is thermally connected to the top plate and bottom plate by thermally conductive strips;

FIG. 21 is a sectional illustration of the thermoelectric generator taken along line 21 of FIG. 19 and illustrating the foil assembly comprising thermoelectric legs disposed on a substrate wherein a temperature gradient across the top and bottom plates results in heat flow in a lengthwise direction through the thermoelectric legs;

FIG. 22 is a top view of the thermoelectric generator taken along line 22 of FIG. 21 and illustrating a series of the thermoelectric legs formed of alternating dissimilar materials and being arranged in rows on the substrate and further illustrating the alignment of the thermally conductive strips with opposite ends of the thermoelectric legs in the rows causing heat to flow lengthwise through the thermoelectric legs.

### DETAILED DESCRIPTION

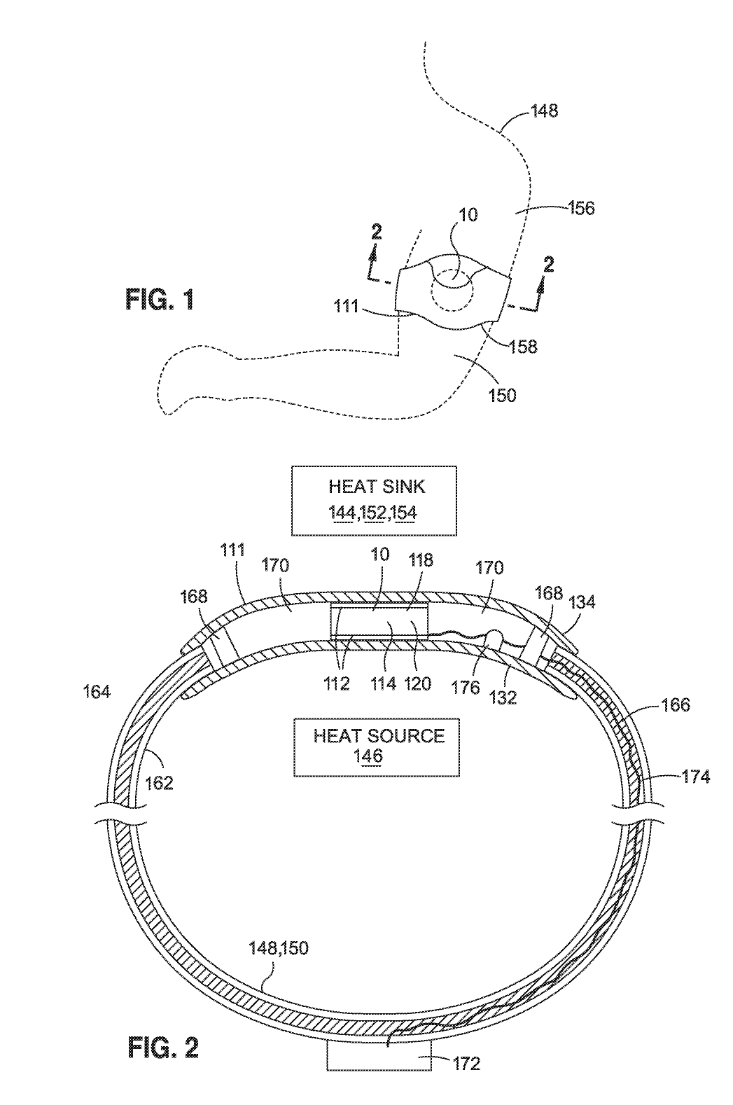

Referring now to the drawings wherein the showings are for purposes of illustrating various embodiments of the disclosure, shown in FIG. 1 is an embodiment of a wearable thermoelectric generator system 111 having one or more thermoelectric generators (TEG) 10 and including one or more features and/or means for optimizing the matching of the thermal resistance of the thermoelectric generator 10 with the thermal resistance of an environment 144 to which the thermoelectric generator 10 may be exposed. For example, the thermoelectric generator 10 may be configured such that the electrical resistance of the thermoelectric generator 10 is substantially equivalent to the electrical resistance of a load. The load may comprise a device such as an electronics module or other device that may be packaged separately from the thermoelectric generator 10 and/or the system 111. In an embodiment, system 111 may be configured such that the electrical resistance of the thermoelectric generator 10 is within at least approximately 50 percent or less of the electrical resistance of the load. The load may comprise any device, without limitation, that may be powered by the system 111 such as a sensor, a rechargeable batter, a light, a mobile or portable communication device such as a cellular telephone, a portable audio player such as a digital audio player, or any other type of device, without limitation.

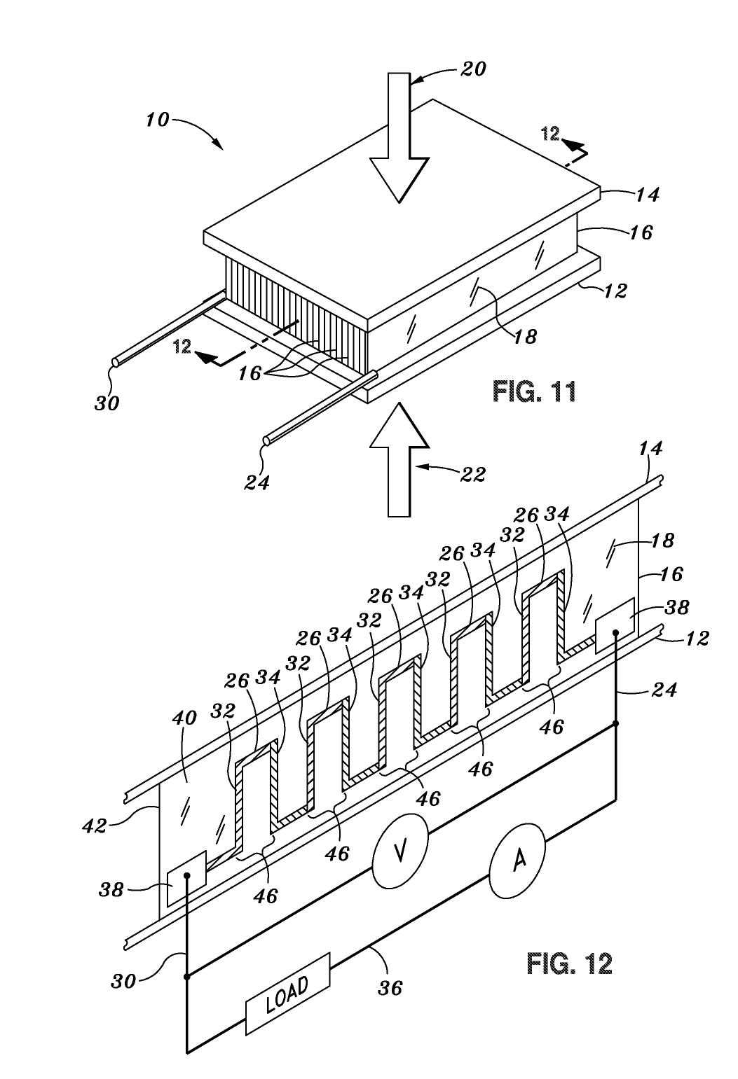

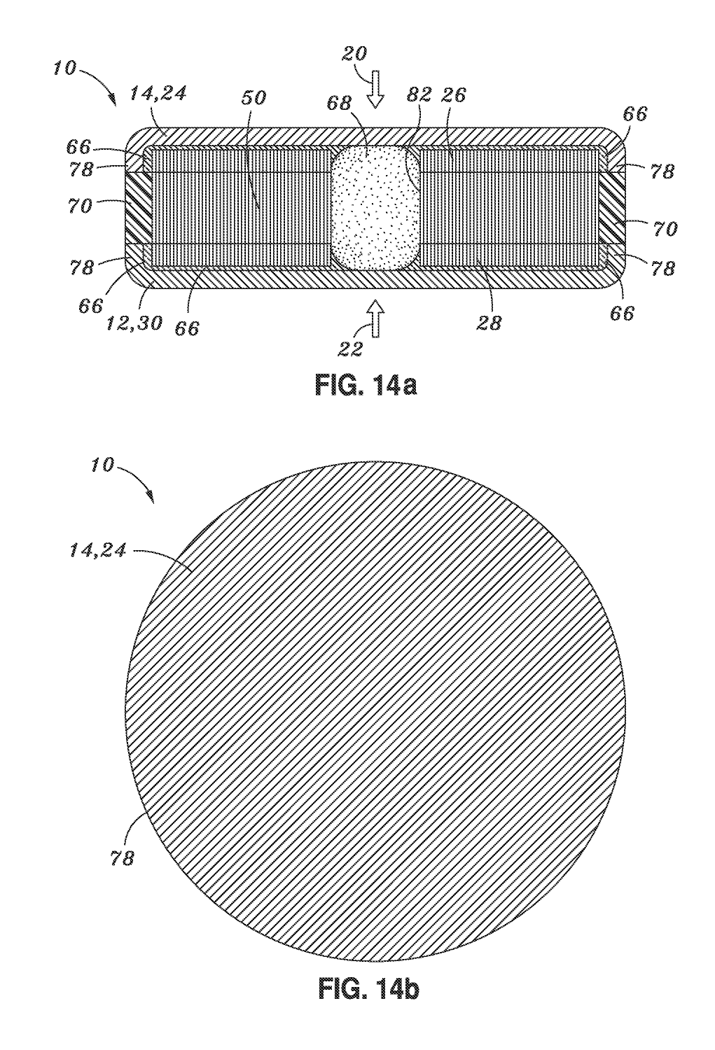

The one or more thermoelectric generators 10 that may be included with the system 111 may be provided in any configuration including, but not limited to, an in-plane configuration and/or a cross-plane configuration. One or more embodiments of the in-plane thermoelectric generator 10 which may be included with the system 111 are described below and illustrated in FIGS. 11-22. Advantageously, an in-plane thermoelectric generator 10 is highly complementary for use in wearable applications such as in the wearable thermoelectric generator system 111 disclosed herein due to the relative ease of adjusting the thermal resistance of an in-plane thermoelectric generator 10 by making geometry adjustments. For example, the thermal resistance of an in-plane thermoelectric generator 10 may be adjusted by adjusting the geometry (i.e., length, width, thickness, etc.—FIG. 13) of the n-type and p-type semiconductor legs of the in-plane thermoelectric generator 10 to obtain optimal thermal matching as described in detail below.

Furthermore, from an electrical standpoint, the in-plane thermoelectric generators 10 may generate a voltage level that is significantly higher than the voltage level of cross-plane thermoelectric generators due to the relatively large quantity of thermocouples arranged in series for in-plane thermoelectric generators 10 as described in detail below in the description referring to FIGS. 11-22. Advantageously, such a high voltage level of in-plane thermoelectric generators 10 may eliminate or minimize the requirement for providing boost electronics for boosting the voltage of the thermoelectric generator 10. By eliminating the requirement for boost electronics, power losses associated with such boost electronics are avoided such that a larger amount of power can be provided to the final electronic device that is powered by the thermoelectric generator 10.

A further advantage provided by an in-plane thermoelectric generator 10 in wearable applications such as in the wearable thermoelectric generator system 111 disclosed herein is the relatively low height and low profile of in-plane thermoelectric generators 10 relative to the larger height associated with bulk cross-plane thermoelectric generators. In this regard, a bulk cross-plane thermoelectric generator may have a relatively large height which may present challenges in integrating the bulk cross-plane thermoelectric generator into a wearable application such as in fabrics or in an article of clothing worn by a user. In addition, thin-film devices such as thin-film cross-plane thermoelectric generators have a relatively small amount of exterior surface area which inhibits the ability to harvest a sufficient amount of heat from the body of a wearer. An attempt to enlarge the exterior surface area of a thin-film cross-plane thermoelectric generator by increasing the size of a heat couple plate or the heat collector of the thin-film cross-plane thermoelectric generator would result in additional thermal interface losses between the thin-film cross-plane thermoelectric generator and such larger heat collectors. In contrast, in the case of an in-plane thermoelectric generator, the thermoelectric generator may be configured with a very low form factor and/or low height yet still provide a naturally large exterior surface for thermal contact with the body of the wearer which significantly increases the heat transfer capability from the body into the in-plane thermoelectric generator 10.

Although FIG. 1 illustrates the wearable thermoelectric generator system 111 in an open or closed band configuration such as an armband 158 mounted to a wearer's arm 156, the system 111 may be provided in any one of a variety of alternative configurations. For example, the system 111 may be provided as a wrist band 160, a chest band 178, and a back pack 190 embodiment as described below. The system 111 may also be provided as a leg band, a head band, a foot band, an article of clothing, a patch, an appliqué, a layer, a strip, an article configured to be carried or held, or any one of a variety of other configurations for exploiting body heat of a user wearing the system 111. The system 111 may also be implemented for use in a structural article, a non-structural article, a system, a subsystem, an apparatus, an assembly, a vehicle, a building, and any one of a variety of other implementations, without limitation. For example, the system 111 may exploit body heat to generate renewable power for electronic applications. The system 111 may also be used in animals (e.g., non-human), such as in livestock for powering RFID sensors for tracing locations of livestock, and/or for monitoring one or more physiological parameters of livestock. In this regard, the heat source 146 may comprise a body of a human, a body of an animal, an inanimate object, or any other type of heat source. The heat sink 152 may comprise ambient air, a fluid including a gas or a liquid of any composition, solid matter of any composition, or any other type of heat sink. In an embodiment, the system 111 may be adapted for use with a heat source 146 having a relatively small temperature difference and a relatively high thermal resistance to the heat sink 152. Advantageously, the system 111 may provide a replacement for batteries and may provide power for applications where batteries are cost-prohibitive. In this regard, the system 111 may be configured to provide autonomous power for the lifetime of an application.

Although not shown, the wearable thermoelectric generator system 111 may provide power for any one of a variety of applications. Non-limiting examples of applications where the system 111 may be implemented to provide power include wireless sensor systems, wireless sensor nodes, ultra-low power radio-transmitters, wireless Body Area Network (WBAN). The system 111 may also be configured to provide power for charging energy storage devices such as rechargeable batteries. In addition, the system 111 may be configured to provide power to sensors and actuators. For example, the system 111 may provide power to sensor for measuring temperature, blood pressure, hearing, breathing, vision, pulse, oxygen saturation, glucose level, electrocardiography (ECG), electroencephalography (EEG), chemical sensors for measuring toxins, and also for implants. The system 111 may also be implemented to power accelerometers for measuring movement, sensors for sensing position, and other measurements.

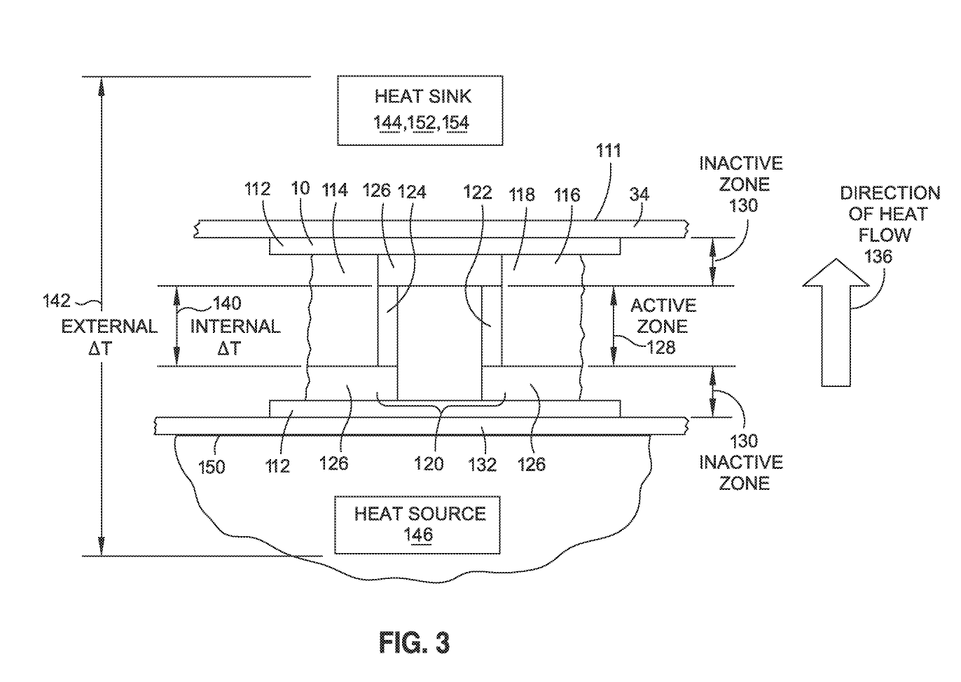

Referring to FIG. 2, shown is a cross section of an embodiment of the wearable thermoelectric generator system 111. The system 111 may include a highly thermally conductive heat collector 132 that may be configured to interface with or be placed in contact with a heat source 146 such as the skin surface 150 of the body 148 of a wearer. When the ambient air is at room temperature (e.g., approximately 68° F. to 72°), the skin surface 150 of the wearer may be at a temperature of approximately 68° F. to 98° F. The system 111 may also be configured to operate when mounted over a layer of material such as fabric or other material covering the wearer's skin in order to prevent a reduction in the temperature of the wearer's skin and maintain heat flow through the thermoelectric generator 10. In this manner, the system 111 may be configured to produce a high level of power by mounting over a covered body 148 part.

The heat collector 132 may be formed of a highly thermally conductive material. For example, the heat collector 132 may be formed of thermally conductive metallic material such as iron including steel such as stainless steel, aluminum, titanium, copper, silver, and any combination or alloy thereof. The heat collector 132 may include metal wires, metal plates, ceramic plates that may be integrated in molded materials that may be placed in contact with the wearer's skin or fabric or other material that may be covering the wearer's skin. The heat collector 132 may also be provided in other configurations to provide a relatively high level of thermal conductance. The heat collector 132 may comprise one or more plates such as relatively thin metallic or ceramic plates. The one or more plates may be curved plates as shown in FIG. 2 to conform to a curvature of the body 148 surface such as the shape of a wrist, upper arm, lower or upper leg including calf or thigh, or any other body part. Non-limiting materials that may be used for forming the heat collector 132 include injection-molded polymers that may optionally be filled with particles having a relatively high thermal conductivity such as graphite particles, metallic particles, ceramic particles, or other types of particles. The material for the heat collector 132 may be a biocompatible material and/or an antibacterial material.

Referring still to FIG. 2, the wearable thermoelectric generator system 111 may also include a heat exchanger 134 configured to transfer heat from the thermoelectric generator 10 to the environment 144 such as to the ambient air. In an embodiment, the heat exchanger 134 may be formed of a material such as one or more of the materials described above for the heat collector 132. However, the heat exchanger 134 may be configured to improve the capability to reject heat to the environment 144. For example, the heat exchanger 134 may be formed with a surface roughness on an outer surface of the heat exchanger 134 to increase surface area for exchanging heat with the environment 144. In this regard, the heat exchanger 134 outer surface may include texture to increase a surface area. The outer surface may include dead holes, pins, trenches, engravings, dimples, grooves, indentations, and other features for increasing surface area.

In an embodiment, the heat exchanger 134 outer surface may have a high emissivity coefficient to maximize radiation such as by providing the outer surface with an anodizing aluminum coating or treatment of by painting the outer surface with high emissivity paint. The inner surface of the heat exchanger 134 and the heat collector 132 may be provided with a relatively low emissivity coefficient to minimize radiation. In addition, the inner surface of the heat exchanger 134 and the heat collector 132 may be provided with a reduced surface area such as by providing the inner surfaces with a smooth surface finish to minimize radiation. The heat exchanger 134 may be curved as shown in FIG. 2 for aesthetic purposes and to minimize sharp corners or protrusions. The heat exchanger 134 may be comprised of one or more plates such as one or more curved metal plates that may generally conform with the heat collector 132 plate.

Material from which the heat exchanger 134 and/or heat collector 132 may be formed includes, but is not limited to, flexible layers of metal mesh formed of polymeric materials and/or metallic materials such as copper and/or silver or other metallic materials or any of the material mentioned above for the heat exchanger 134 and/or heat collector 132. The heat exchanger 134 and/or heat collector 132 may also be formed of relatively thin layers of metals or other non-metallic materials. In a non-limiting embodiment, the heat exchanger 134 and/or heat collector 132 may be formed of mesh material such as a mesh of fabrics. The heat exchanger 134 may be formed of such mesh material and/or metal coated yarn to increase thermal conductivity and for aesthetic reasons.

Referring still to FIG. 2, the system 111 may include at least one thermoelectric generator 10 although the system 111 may include multiple thermoelectric generators 10 that may be mounted to the system 111 in spaced relation to one another in order to reduce the thermal path from the heat source 146 (e.g., the wearer's body) to the heat exchanger 134 as described in greater detail below. In FIG. 2, the thermoelectric generator 10 is shown in an embodiment wherein the thermoelectric generator 10 includes heat couple plates 112 that may be placed between the heat collector 132 and the heat exchanger 134. However, the system 111 may be configured in an embodiment wherein a core 118 of the thermoelectric generator 10 may be placed directly between the heat collector 132 and the heat exchanger 134 and the thermoelectric generator 10 may be provided without heat couple plates 112. The core 118 may comprise the substrate 114 material and a plurality of thermocouples disposed on the substrate 114. The heat collector 132 and/or the heat exchanger 134 may extend at least across a width of the core 118 and may be mounted directly to the core 118 of the thermoelectric generator 10. By omitting the heat couple plates 112, the external thermal resistance of the system 111 may be reduced in comparison to the thermal resistance in a thermoelectrically active zone 128 of the thermocouples of the thermoelectric generator 10 as described in greater detail below.

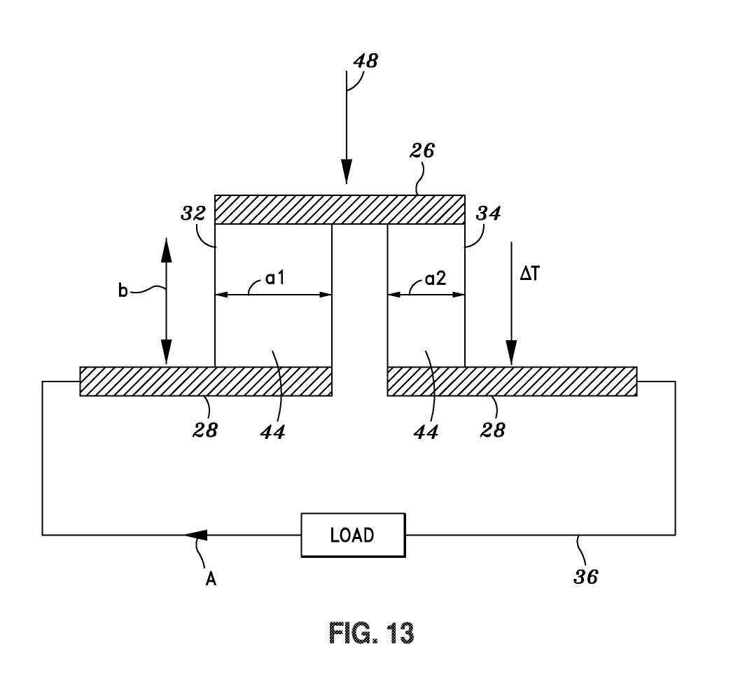

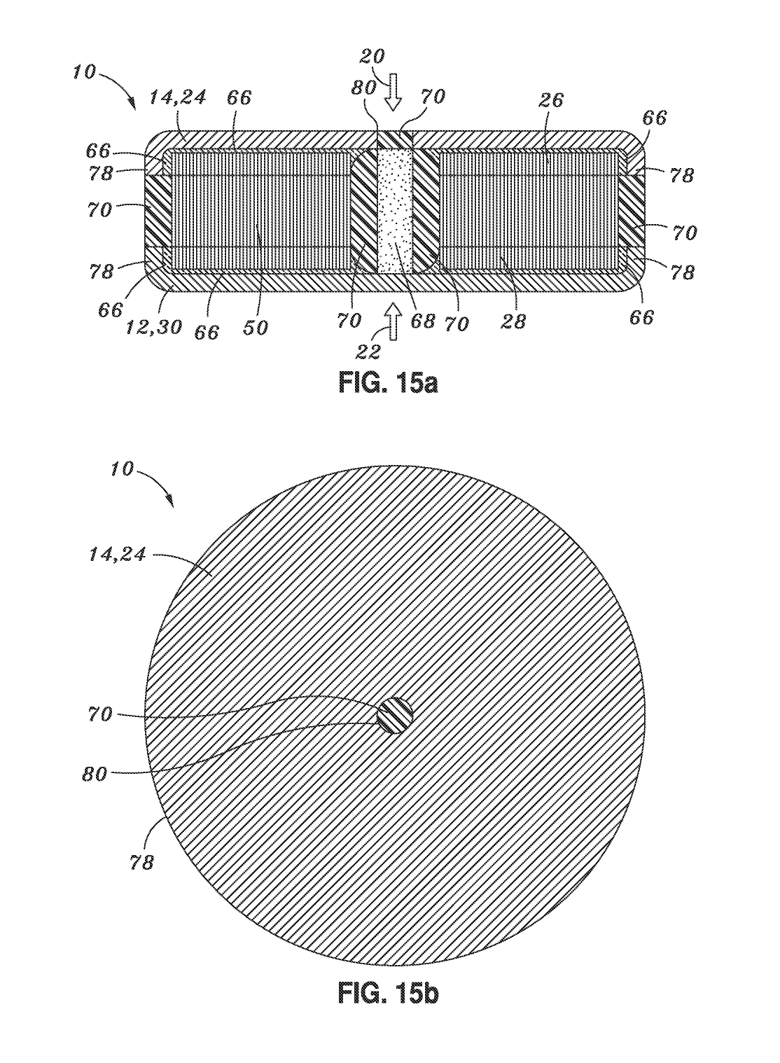

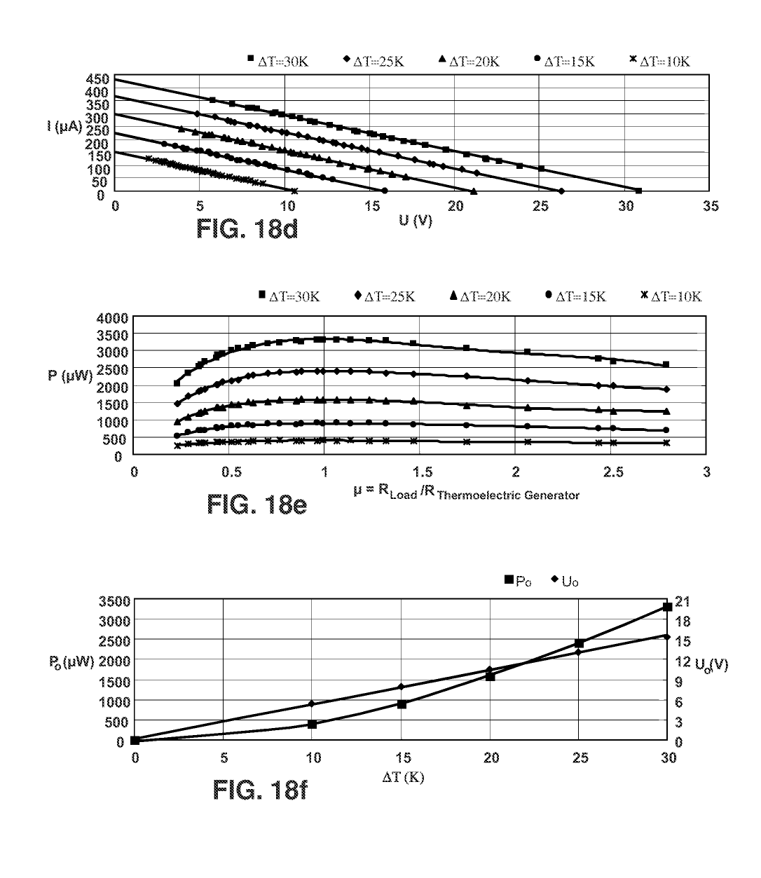

As indicated above, the wearable thermoelectric generator system 111 may include one or more thermoelectric generators 10 that may be provided in an in-plane configuration and/or in a cross-plane configuration. For example, the thermoelectric generator 10 may be provided in an in-plane configuration in a square-shape arrangement as illustrated in FIGS. 11-12 and described in greater detail below. The thermoelectric generator 10 may also be provided in an in-plane configuration comprising a coiled or spirally-wound (i.e., round) shape as illustrated in FIGS. 14a-18f and described below. Even further, the thermoelectric generator 10 may be provided in a planar configuration as illustrated in FIGS. 19-22 and described in greater detail below. It should be noted that although FIGS. 1, 8 and 9 illustrate the thermoelectric generator 10 having a generally round shape, the TEG may be provided in a shape other than a round shape. For example, for a square-shape arrangement of the thermoelectric generator 10 shown in FIGS. 11-12 or a planar configuration of the thermoelectric generator 10 shown in FIGS. 19-22, the thermoelectric generator 10 may have a non-round shape such as a square shape or a rectangular shape. Advantageously, the in-plane configuration of the thermoelectric generator 10 may be preferably implemented in a wearable thermoelectric generator system 111 due to the ability to easily adjust the thermal resistance of the thermoelectric generator 10 to thermally match the environment 144 of the thermoelectric generator 10.

The thermoelectric generator 10 may include a plurality of thermocouples. Although the thermocouples may be formed of a suitable thermoelectric material, the thermocouples may be advantageously be formed using Bi₂Te₃ type material due to the relatively high thermoelectric figure of merit exhibited by Bismuth-Telluride type material in the room temperature range. In an embodiment, the thermoelectric generator 10 may comprise a thermopile or a plurality of thermocouples that may be captured between or sandwiched between a pair of heat couple plates 112 as illustrated in FIG. 2 and described below with reference to the thermoelectric generator 10 embodiments illustrated in FIGS. 11-22.

One or more of the thermoelectric generators 10 may be sealed from the elements using a sealant or encapsulant. For example, as indicated below in the description of the thermoelectric generator 10 embodiments shown in FIGS. 11-22, the thermoelectric generators 10 may be sealed within the heat couple plates 112 using RTV silicones, UV-cured adhesives, and other sealants in order to protect thermoelectric generators 10 from environmental influences (e.g., moisture, dirt, chemicals, mechanical impact) and for safety reasons while wearing the wearable thermoelectric generator system 111 on the body.

The heat couple plates 112 may be formed of a material that is compatible with the thermocouple material system as described in detail below. For example, materials for forming the heat couple plates 112 include, but are not limited to, anodized aluminum, stainless steel, copper such as with insulating layer such as alumina, or any of the above-mentioned materials from which the heat exchanger 134 and/or heat collector 132 may be formed. The heat couple plates 112 may be provided with an intermediate layer such as a layer of nickel or tin which may be deposited with a vapor deposition process or a galvanic process to improve adhesion to an alumina film of the heat couple plates 112.

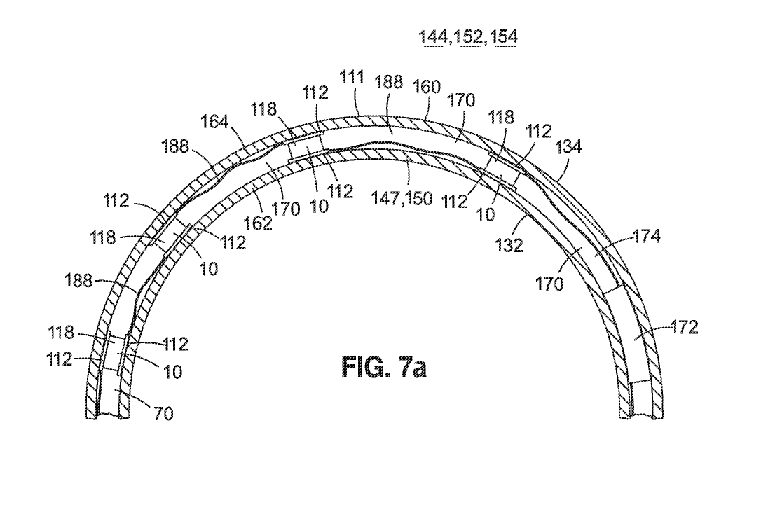

As shown in FIG. 1, a single thermoelectric generator 10 may be included with the wearable thermoelectric generator system 111 or multiple thermoelectric generators 10 may be included with the system 111 as shown in FIGS. 6-8 and described below. Multiple thermoelectric generators 10 electrically connected in series may provide increased voltage. One or more of the multiple thermoelectric generators 10 may also be electrically connected in parallel to increase the amperage of the current that may be provided to a load. The multiple thermoelectric generators 10 may be distributed across an energy harvesting area such as the skin surface 150 of a wearer's body 148 in order to minimize thermal resistance of the heat collector 132 and the heat exchanger 134 and thereby maximize the power generated by the thermoelectric generator 10.

Referring still to FIG. 2, the wearable thermoelectric generator system 111 may include one or more layers of material for fastening or attaching to a wearer's body. For example, the system 111 may include an inner material layer or inner material layer 162 and an outer material layer or outer material layer 164. The inner and/or outer material layer 162, 164 (e.g., inner and outer material layer) may be formed of a rigid material comprised of metallic or non-metallic material, or the inner and/or outer material layer 162, 164 a flexible material to substantially conform to a body contour of the wearer's body. The inner and outer material layer 162, 164 may be coupled to the heat collector 132 and/or to the heat exchanger 134. For example, the inner and outer material layer 162, 164 may be bonded to the ends of the heat collector 132 and/or the heat exchanger 134. A thermally insulating middle layer 166 may be included between the inner and outer material layer 162, 164. For example, the thermally insulating middle layer 166 may comprise a layer of foam or a relatively flexible plastic material such as polycarbonate.

The thermally insulating middle layer 166 may be formed of a molded material or a polymeric material such as liquid foam which may provide a relatively low thermal conductivity between the inner and outer material layer 162, 164. The thermally insulating middle layer 166 may minimize the shunting of heat flow from the inner layer 162 into the outer layer 164. In this manner, the thermally insulating middle layer 166 may cause a majority of heat collected from the wearer by the inner layer 162 to flow through the thermoelectric generator 10. In a further embodiment, the band configuration may include the outer material layer 164 and the thermally insulating middle layer 166 without the inner material layer 162. In such an arrangement, the thermally insulating middle layer 166 may be mounted on a side of the outer material layer 164 such that the thermally insulating middle layer 166 may contact the skin surface of a wearer.

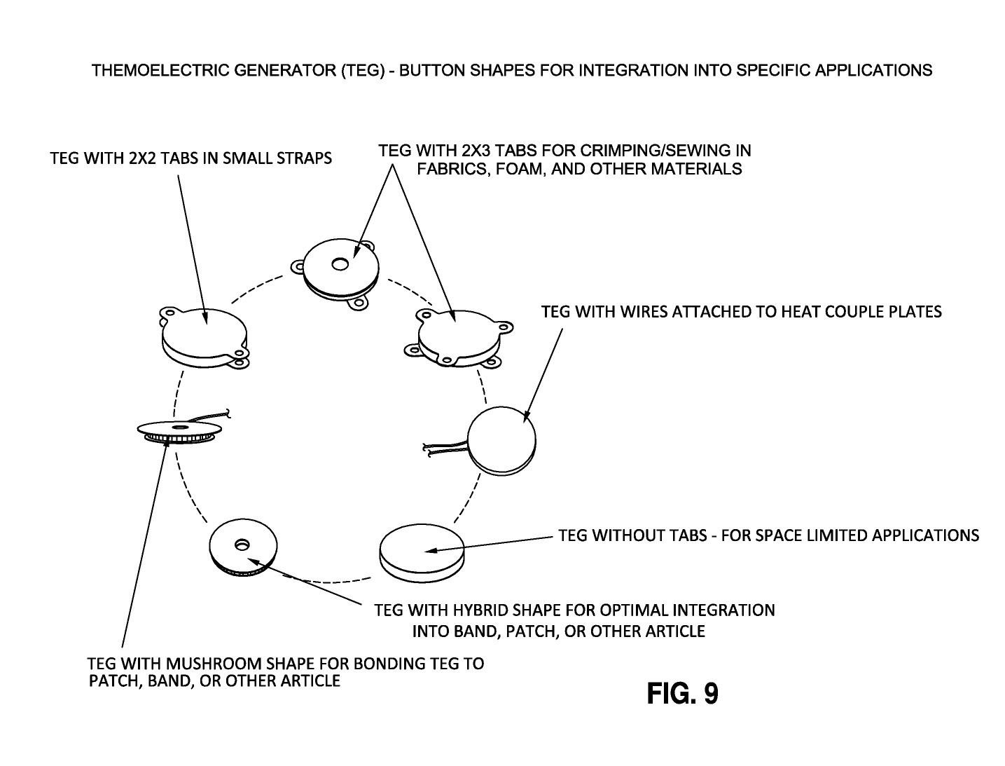

The inner material layer 162 may be formed of a biocompatible material and/or an antibacterial material. In an embodiment, the inner material layer 162 may be formed of a material that is preferably comfortable and/or soft against human skin and is also preferably a durable material such as suede or other material. The outer material layer 164 may optionally be formed of the same material as the inner material layer 162. In an embodiment, the outer material layer 164 may be formed of an aesthetically pleasing material and which may be provided in any one of a wide range of colors including camouflage and which preferably has a durable composition for exposure to dirt and moisture. Waterproof fabrics such as Gortex^{TM} may be used to form the inner and outer material layer 162, 164. In order to enhance the waterproof capability, the inner and outer material layer 162, 164 may be sealed along inner surfaces of the heat exchanger 134 and heat collector 132. For embodiments of the wearable thermoelectric generator system 111 where the thermoelectric generators 10 (e.g., thermoelectric generator 10 buttons—FIG. 9) are integrated directly into the inner and/or outer material layer 162, 164, the thermoelectric generator 10 may be sealed to the waterproof fabric to provide a hermetically-sealed and contamination-proof package including integrated thermoelectric generator 10 buttons.

Although not shown, the wearable thermoelectric generator system 111 may include flaps which can be adjusted (e.g., partially opened or closed) to control the amount of heat exchanger 134 surface area exposed to ambient air as a means to control heat flow from the heat exchanger 134 to the ambient air. As indicated above, the thermal resistance of the body may be dependent upon the activity level of the body. For example, at a high activity level, such as when running, the increase in blood circulation may significantly decrease the thermal resistance of the skin to a much lower level than when the body is at rest, and allowing the transfer of heat more efficiently from the body core to the skin surface. The heat flow per unit area (i.e., the heat density) may vary by up to one order of magnitude from a low level such as during resting or sleeping (e.g., approximately 40 W/m²) to a high level such as during running (e.g., approximately 550 W/m²). Advantageously, flaps may provide a means to alter the thermal resistance of the thermoelectric generator 10 to match the change in thermal resistance of the wearer's body and the change in heat flow into the thermoelectric generator 10 as a result of the change in activity level.

In an embodiment, flaps may be mounted to the outer material layer 164 of the wearable thermoelectric generator system 111or to another component of the system 111. The flaps may provide a means to adjust the flow of heat through the thermoelectric generator 10 wherein a wearer of the system 111 may move or adjust the flap of material to cover a portion of the heat exchanger 134 or to cover an entirety of the heat exchanger 134 to control heat flow from the heat exchanger 134 to the ambient air. For example, the flap may be moved to at least partially close off the exposure of the thermoelectric generator 10 to the ambient air 154 when the wearer moves from an indoor environment 144 at room temperature (e.g., approximately 60° F. to 72° F.) to an outdoor environment 144 where the ambient air 154 is at a relatively colder temperature (e.g., approximately 0° F. to 50° F.). The flaps may provide a means to increase the thermal resistance. It should be noted that the system 111 may include alternative mechanisms for adjusting heat flow through the thermoelectric generator 10 and is not limited to flaps. For example, the system 111 may include a zipper that may be partially or fully zipped or closed to partially or fully cover the heat exchanger 134 or the portion of the thermoelectric generator 10 that may be exposed to ambient air. The system 111 may also include adjustable vents such as sliding vents or vents that may be buttoned or snapped to partially or fully cover the heat exchanger 134 or the material covering at least a portion of the heat exchanger 134.

The inner and outer material layer 162, 164 may be formed of material having a relatively high level of thermal conductivity. In an embodiment, the inner and/or outer material layer 162, 164 may include coated layers of carbon-nanotubes, metal wires or meshes, graphite material, metal-coated yarn, and other materials that may be integrated into the inner and/or outer material layer. In this regard, the inner material layer 162 may effectively increase the surface area of the heat collector that is contact with the wearer. The outer material layer 164 may effectively increase the surface area of the heat exchanger that is exposed to the ambient air. The inner and outer material layer 162, 164 may include elements such as reinforcing strips that may be integrated into the inner and outer material layer 162, 164 in order to provide reinforcement at high-stress areas such as along edges and to increase dimensional stability of the wearable thermoelectric generator system 111. The inner and outer material layer 162, 164 may be assembled or integrated into the system 111 by any suitable assembly means including, but not limited to, by sewing, with mechanical fasteners, with adhesives including curable adhesive and/or adhesive tape, or other suitable means. Seams of the inner and outer material layers 162, 164 may be installed within the gaps between the heat collector 132 and the heat exchanger 134.

Referring to FIG. 2, the inner and outer material layer 162, 164 may be attached to the heat collector 132 and/or heat exchanger 134 such as by bonding and/or mechanically fastening the inner and outer material layer 162, 164 between the heat collector 132 and heat exchanger 134 or attaching to the outer surfaces of the heat collector 132 and heat exchanger 134. Spacers 168 made from polymeric material may be included at the terminal ends of the inner and outer material layer 162, 164 at the attachment point to the heat collector 132 and heat exchanger 134. The spacers 168 may mechanically protect the thermoelectric generator 10 by mechanically stabilizing the package and absorbing mechanical forces such as may occur if the heat exchanger 134 bumps against or contacts a hard surface. The spacers 168 may also prevent crimping or deforming of the terminal ends of the heat collector 132 and heat exchanger 134. The spacers 168 may be formed of relatively low thermally conducting material.

In FIG. 2, in an embodiment, an insulation layer 170 may be installed in the region between heat collector 132 and heat exchanger 134 on one side or both sides of the thermoelectric generator 10. The insulation layer 170 may fill at least partially fill a gap between the sides of the thermoelectric generator 10 and the ends of the inner and outer material layer 162, 164 at the attachment thereof to the heat collector 132 and/or the heat exchanger 134. In this regard, the insulation layer 170 may extend between the sides of the thermoelectric generator 10 and the ends of the inner and outer material layer 162, 164. The insulation layer 170 may substantially surround all sides of the thermoelectric generator 10. The insulation material such as Aerogel^{TM} or other thermally insulative material of the insulation layer 170 may be installed between the heat collector 132 and the heat exchanger 134 to minimize heat flow out of the sides of the thermoelectric generator 10.

Advantageously, the insulation layer 170 may also prevent or minimize the shunting of thermal flow from the heat collector 132 to the heat exchanger 134 such that a majority of heat collected by the heat collector 132 and the inner material layer 162 flow through the thermoelectric generator 10. In this regard, the insulation layer 170 may prevent convection heat transfer and radiative heat transfer between the heat collector and the heat exchanger. In addition, the insulation layer 170 may provide mechanical support for the heat exchanger 134, heat collector 132, and thermoelectric generator 10, and may also hermetically seal or protect the thermoelectric generator 10 from environmental elements such as moisture, chemicals, dirt, and debris. Furthermore, the insulation layer 170 may improve the aesthetics of the system.

A clasping mechanism (not shown) for cinching or strapping the wearable thermoelectric generator system 111 to a wearer's arm 156 or other body 148 part may be included with the system 111. The clasping mechanism may comprise Velcro™, buckles, snaps, or any one of a variety of other clasping mechanisms. In an embodiment, the inner and outer material layer 162, 164 may be formed of a unitary piece of neoprene, lycra, spandex or other resiliently stretchable material having relatively high thermal insulating capabilities. Such a unitary material may be coupled to the terminal ends of the heat collector 132 and heat exchanger 134 such that the armband 158, wrist band 160, or other embodiment of the system 111 may be installed by slipping over the wearer's arm 156 or leg and may be secured to the wearer by friction.

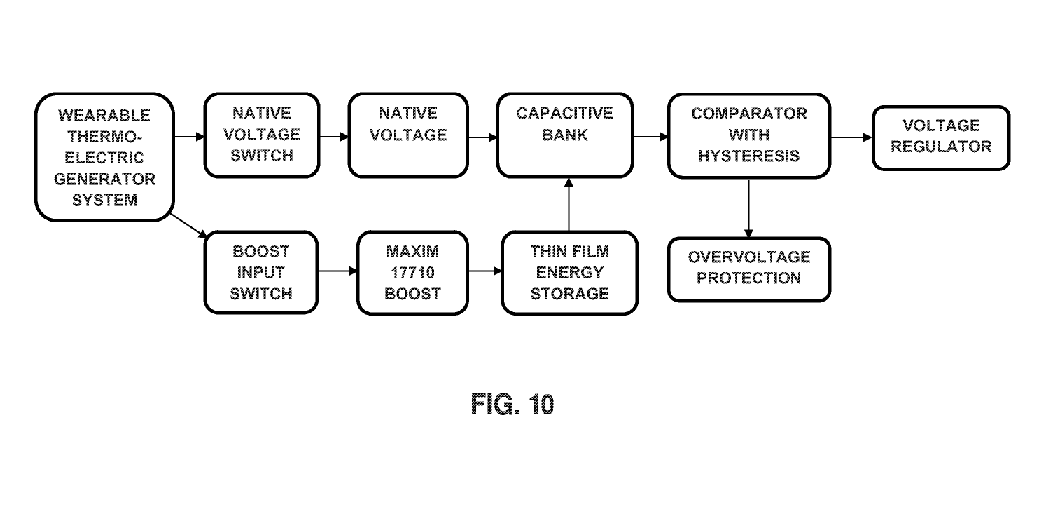

Referring to FIGS. 2 and 10, the wearable thermoelectric generator system 111 may include an electronics 172 box or compartment or assembly. The electronics 172 may be configured to house electronics 172 for managing the system 111. In this regard, the electronics 172 may comprise ultra-low power management for the thermoelectric generator 10. The electronics 172 may also comprise the final electronics such as a sensor, a charging system, or other final electronics devices described above. The electronics 172 may be installed with the system 111 as an electrically insulated box that may be mounted to the inner and/or outer material layer. The system 111 may be configured such that the electrical resistance of the thermoelectric generator 10 is substantially equivalent to the electrical resistance of the load (e.g., final electronics) powered by the thermoelectric generator 10. The thermoelectric generator 10 may be electrically connectable to the load such as via one or more wires 174 as shown in FIG. 2. The wires 174 may be fixed in position by one or more wire constraints 176. The wires 174 may also preferably be arranged in a manner that accommodates the stretching of the inner and outer material layer 162, 164 when the system 111 is worn by a user. The wires 174 may be at least partially encapsulated in the thermally insulating middle layer 166 and may terminate at the thermoelectric generator 10. Electrical connection 188 between the electronics 172 and the thermoelectric generator 10 may also be facilitated by insulated wiring, electrical conductors such as wires that may be woven into material layers, flexible wires mounted on polyimide foil, screen-printed electrically conductive patterns on material layers, metal coated yarn woven into fabrics, and other embodiments that provide an electrical path. Electrical wiring may be interconnected to the thermoelectric generator 10, the electronics 172, and/or to other devices by soldering, spot-welding, electrically conductive adhesive, or by other means.

In an embodiment, the thermoelectric generator 10 may be configured such that the electrical resistance of the thermoelectric generator 10 is substantially equivalent to the electrical resistance of the load such as within at least approximately 50 percent of the electrical resistance of the load or within approximately 20 percent of the electrical resistance of the load. However, the system 111 may be configured such that the electrical resistance of the thermoelectric generator 10 is within any ratio of the electrical resistance of the load. As indicated above, maximum electrical power may be transferred if the electrical resistance of a load or electronic circuitry substantially matches the electrical resistance of the thermoelectric generator 10. In this regard, the electronics 172 of the wearable thermoelectric generator system 111 may be configured to control or manage the thermoelectric generator 10 power output to provide a boost to a power energy storage component (e.g., a rechargeable battery—not shown) and/or to final electronics (e.g., a sensor—not shown). Alternatively, the electronics 172 of the system 111 may be configured to manage the thermoelectric generator 10 power output to bypass an energy storage component (e.g., battery) and provide power directly to the final electronics. In an embodiment, the electronic may be configured to switch between both modes. The electronics 172 may further be configure to provide power management functions including, but not limited to, rectification, protection against excessive voltage to the final electronics, and protection against unwanted discharge of an energy storage component such as a battery.

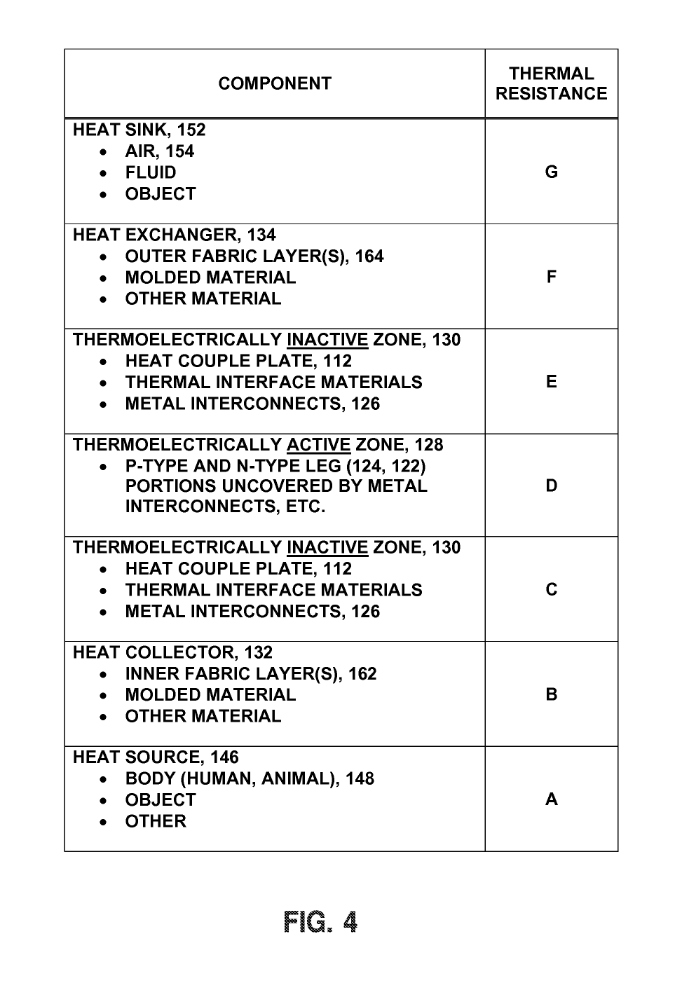

Referring to FIG. 3, shown is a schematic illustration of one of the thermocouples of the thermoelectric generator 10 of the wearable thermoelectric generator system 111. Also shown is an environment 144 to which the thermoelectric generator 10 may be exposed. The environment 144 may include a heat source 146 comprising a body 148 of a wearer of the system 111. In FIG. 3, the heat collector 132 is in thermal contact with the thermoelectric generator 10 and with the heat source 146 which may comprise the wearer's body 148 at the skin surface. The environment 144 may also include a heat sink 152 comprising ambient air 154 to which the heat exchanger 134 is exposed. The heat exchanger 134 is also in thermal contact with the thermoelectric generator 10. In the example shown, the thermoelectric generator 10 may include heat couple plates 112 in contact with the heat collector 132 and heat exchanger 134. The heat flow direction 136 is also shown.

In FIG. 3, the thermoelectric generator 10 includes at least one thermocouple 120 comprising an n-type semiconductor leg 122 and a p-type semiconductor leg 124 deposited onto a top side 116 of a substrate 114 such as a Kapton^{TM} substrate 14. The n-type and p-type legs 122, 124 may be interconnected by metal interconnects 126. The thermocouple 120 may be divided into a thermoelectrically active zone 128 and thermoelectrically inactive zones 130 at opposite ends of the thermocouple. The thermoelectrically inactive zones 130 comprise the portion of the n-type and p-type legs 122, 124 that are covered by the metal interconnects 126. The heat couple plates 112 also form part of the thermoelectrically inactive zones 130 of the thermocouple.

As indicated above, the wearable thermoelectric generator system 111 disclosed herein is provided with a variety of different mechanisms for optimizing the matching of the thermal resistance of the thermoelectric generator 10 with the thermal resistance of the environment 144. More specifically, the system 111 includes a variety of means by which the thermal resistance of the thermoelectrically active zone 128 is substantially equivalent to, or within a predetermined range (e.g., within approximately 50%) of, the sum of the thermal resistances in series of the heat sink 152, the heat source 146, and one or more components of the wearable thermoelectric generator system 111. In this regard, the system 111 includes a variety of features for optimizing the thermal resistances of the thermoelectric generator 10 and the environment 144 such that the internal temperature gradient 140 is substantially equivalent to the total or external temperature gradient 142, or within a predetermined range (e.g., within approximately 150%) of the total or external temperature gradient 142. In an embodiment, the thermal resistance of the environment 144 comprises a series of thermal resistances of the human body 148 (i.e., heat source 146), heat collector 132, and heat exchanger 134 to the surrounding air 154 (i.e., heat sink 152). All thermal resistances are in series. For maximum power generation by the thermoelectric generator 10, the thermal resistance of the thermocouple 120 in the thermoelectrically active zone 128 is substantially equivalent to all other thermal resistances in series. However, the system 111 may be configured such that the thermal resistance of the thermocouple 120 in the thermoelectrically active zone 128 is within a predetermined range (e.g., within approximately 50%) of the sum of the thermal resistances in series.

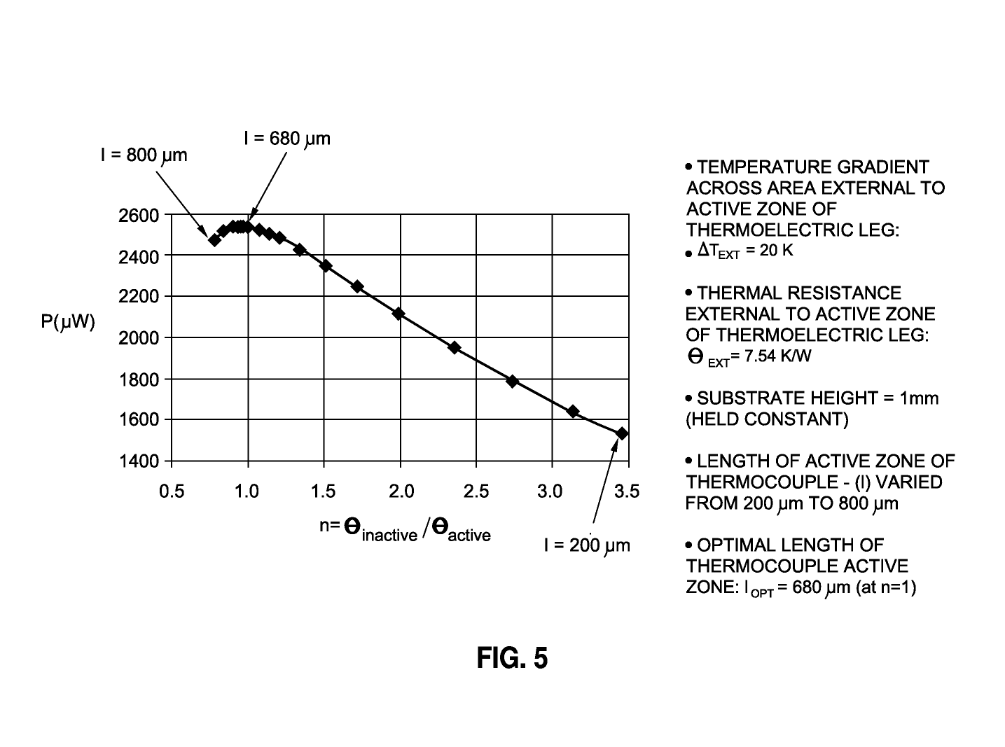

In the chart of FIG. 4, the components associated with the wearable thermoelectric generator system 111 are assigned a letter code representing a thermal resistance of such component. For example, component D represents the thermal resistance of the thermoelectrically active zone 128 of the thermocouple. Components C and E represent the thermoelectrically inactive zones 130 of the thermocouple. For example, component C represents the heat couple plate, the thermal interface materials such as adhesives, and the metal interconnects 126 or pads connecting the semiconductor legs 122, 124. Components A, B, F, and G represent other thermal resistances of the environment 144 and/or system 111 that are not thermoelectrically active. The system 111 as disclosed herein includes a variety of mechanisms for optimizing thermal resistance matching of the thermoelectric generator 10 with the thermal resistance of the environment 144 in order to provide maximum power output. In the example, shown in FIG. 4, the system 111 may be configured such that D may be thermal matched to the sum of at least one of components A, B, C, E, F, and G which represent thermal resistances of the environment 144 and thermal resistances of system 111 components that are not thermoelectrically active. However, in an embodiment, the system 111 may be configured such that component D may be thermal matched to the sum of at least one of components B, C, E, and F which represent thermal resistances of at least a portion of the environment 144.

In this regard, the wearable thermoelectric generator system 111 may advantageously include a thermoelectric generator 10 configuration that facilitates optimization of thermal matching. For example, the human body 148 has a relatively high thermal resistance due to fat, muscle, and tissue that surrounds the core. The thermal resistance of a thermoelectric generator 10 is therefore also preferably high in order to match the thermal resistance of the body 148. A thermoelectric generator 10 with an in-plane configuration may advantageously facilitate the matching of the thermal resistance of the environment 144 by adjusting the geometry of the thermocouples. For example, the n-type and/or p-type semiconductor legs 122, 124 are defined by a length, a width, and a thickness as mentioned below in the descriptions of the thermoelectric generator 10 embodiments shown in FIGS. 11-22. The thermal resistance of the thermoelectrically active zone 128 may be adjusted by adjusting the length, the width, and/or the thickness of the n-type and/or p-type semiconductor legs 122, 124 and/or by selecting a material composition for the n-type and/or p-type semiconductor legs 122, 124. In addition, thermal resistance may be adjusted by adjusting the material and/or geometry of the metal interconnects 126, the density of the area of coverage of the n-type and/or p-type semiconductor legs 122, 124 on the foil substrate 14, the thickness of the foil substrate 14, the quantity of thermocouples, and other variables.

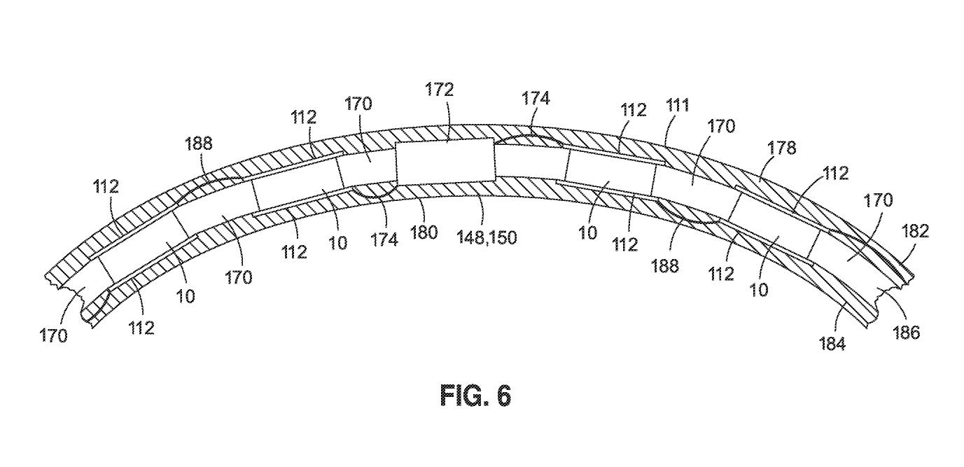

Referring to FIG. 5, shown is a plot of power output of a thermoelectric generator 10 calculated as a function of the thermal matching of the active zone of a thermocouple with the inactive zones of the thermocouple. It should be noted that the thermoelectric generator 10 of FIG. 5 is adapted primarily for industrial use and not for use in a wearable thermoelectric generator system 111. However, the plot of FIG. 5 illustrates the ability to adjust the geometry (i.e., length) of the n-type and p-type semiconductor legs 122, 124 to achieve thermal matching of the thermoelectrically active zone 128 to the thermoelectrically inactive zones 130. The thermoelectric generator 10 of FIG. 5 was subjected to a temperature gradient of 20 Kelvin across the height (i.e., 1 mm) of a Kapton™ substrate 114 upon which n-type and p-type semiconductor legs 122, 124 of BiTe-type material were disposed. The thermal resistance of the area external to the thermoelectrically active zone 128 (i.e., the thermoelectrically inactive zones 130) was determined to be 7.54 Kelvin per Watt. While maintaining the substrate 114 at a constant height of 1 mm, the height of the thermoelectrically active zone 128 of the thermocouple 120 was varied from 200 microns to 800 microns. Power output was calculated for each variation in height of the thermocouple. As can be seen in the plot, a maximum power output of approximately 2550 micro-Watts occurred when the thermal resistance of the thermoelectrically inactive zones 130 was substantially equivalent to the thermal resistance of the thermoelectrically active zone 128 (i.e., ratio n=1) and which corresponds to a length of 1680 microns for the n-type and p-type semiconductor legs 122, 124. As may be appreciated, one or more of a variety of other parameters may be adjusted to achieve thermal matching for a wearable thermoelectric generator system 111 and which may advantageously achieved in a cost-effective manner with an in-plane thermoelectric generator 10.

Referring to FIGS. 6-9, shown are additional embodiments of the wearable thermoelectric generator system 111 for which thermal matching may be achieved by adjusting one or more parameters of the components that make up the system 111. It should also be noted that any of the materials, construction techniques, and arrangement options discussed above in regard to the armband 158 embodiment shown in FIGS. 1 and 2 may be incorporated, in whole or in part, into any of the embodiments disclosed herein and including the embodiments shown in FIGS. 6-9 and described below. Likewise, any of the materials, construction techniques, and arrangement options discussed below in regard to the embodiments shown in FIGS. 6-9 may be incorporated, in whole or in part, into the armband 158 embodiment shown in FIGS. 1 and 2.

In FIG. 6, shown is a portion of a chest band 178 embodiment of the wearable thermoelectric generator system 111. The embodiment may include at least one thermoelectric generator 10 which may comprise a thermoelectric generator 10 core 118 and, optionally, one or more heat couple plates 112 on the upper and/or lower sides of the thermoelectric generator 10. The thermoelectric generators 10 may be integrated into a band which may be formed of molded material 180. However, the chest band 178 may be formed of flexible fabric material similar to the construction of the armband 158 shown in FIG. 2 and described above. The molded material 180 may comprise at least one layer and, more preferably, three layers. For example, the layers may include a top layer 182 and a bottom layer 184 made from highly thermally conductive material, and a middle layer 186 made from relatively low thermally conductive material. Heat couple plates 112 may optionally be integrated into the top layer 182 and/or the bottom layer 184. The top and/or bottom layer 182, 184 may be formed of any metallic or non-metallic material. For example, the top layer 182 and the bottom layer 184 may include copper foil sheet that may be separated by a material of relatively low thermal conductivity layer 186 such as foam or foam rubber to conform to the wearer and provide an improved thermal path to the thermoelectric generators 10.

The chest band 178 embodiment may include electrical connections such as wiring or conductive mesh extending between and electrically connecting the thermoelectric generators 10. The thermoelectric generators 10 may be electrically connected in series and/or in parallel depending upon voltage and current requirements and on other factors. An electronics 172 compartment may be included for power management in a manner similar to the electronics 172 module described above for the armband 158 embodiment shown in FIG. 2. The electronics 172 compartment may be integrated into the system 111 between the top layer 182 and the bottom layer 184. A thermally insulating middle layer 186 may be installed between the thermoelectric generators 10 and the electronics 172 compartment. Although identified as a chest band 178, the embodiment illustrated in FIG. 6 may be worn at any location and is not limited to wearing on the chest of a user. In this regard, the embodiment shown in FIG. 6 represents a system 111 for application to a medium sized area.

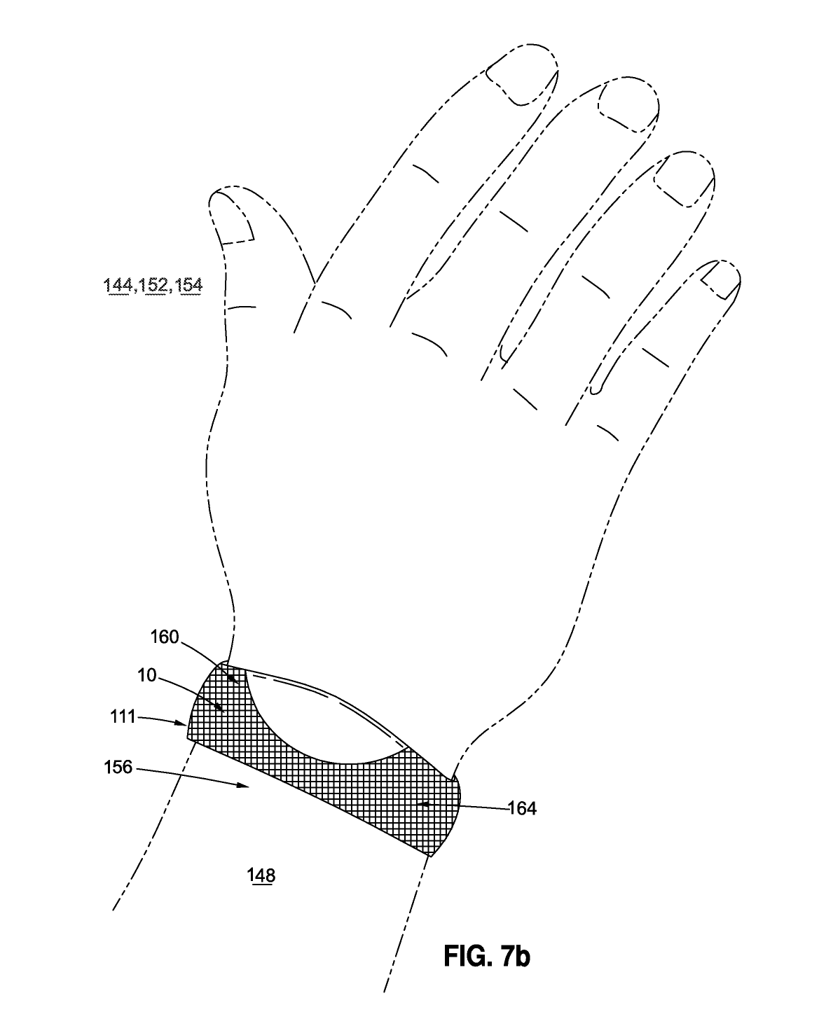

In FIG. 7a, shown is a portion of a wrist band 160 embodiment of the wearable thermoelectric generator system 111. The wrist band 160 embodiment may represent a system 111 for application to a relatively small area. The wrist band 160 embodiment may include at least one thermoelectric generator 10 such as a thermoelectric generator 10 core 118 sandwiched between bands (e.g., inner and outer material layers 162, 164) of flexible, highly thermally conductive material that may form a closed loop such as a stretch band. The wrist band 160 embodiment may include a thermally insulating layer between the inner and outer layers. The inner and outer layers may be formed of metal foil carbon-nanotube fabric, graphite, highly thermally conductive mesh fabric, or other material. The inner layer may comprise a comfortable and bio-compatible material. The wrist band 160 embodiment may include a thin, aesthetic, decorative cover or coating, for example, such as a highly thermally conductive mesh fabric or similar material. The thermoelectric generators 10 may optionally include heat couple plates 112. Electrical connections may be routed between the inner and outer layers to electrically connect the thermoelectric generators 10 in any one of the means described above.

FIG. 7b illustrates an additional wrist band 160 embodiment of the wearable thermoelectric generator system 111 formed in an open C-shape and sized and configured to clasp or be clamped around the wrist of the body 148 of a wearer. In this regard, the C-shape wrist band 160 embodiment may have a generally rigid but resiliently flexible layer (not shown) for maintaining shape when worn on a user's wrist. The wrist band 160 embodiment may include inner and/or outer material layers 162, 164 including thermally conductive material such as relatively thin metallic sheet such as thin copper sheet. The sheets of the inner and outer layers 162, 164 may be separated by thermally insulative material such as foam or plastic or other material. The wrist band 160 may include one or more thermoelectric generators 10 that may be mounted to the system 111 and electrically interconnected in a manner similar to any one of the embodiments disclosed herein.

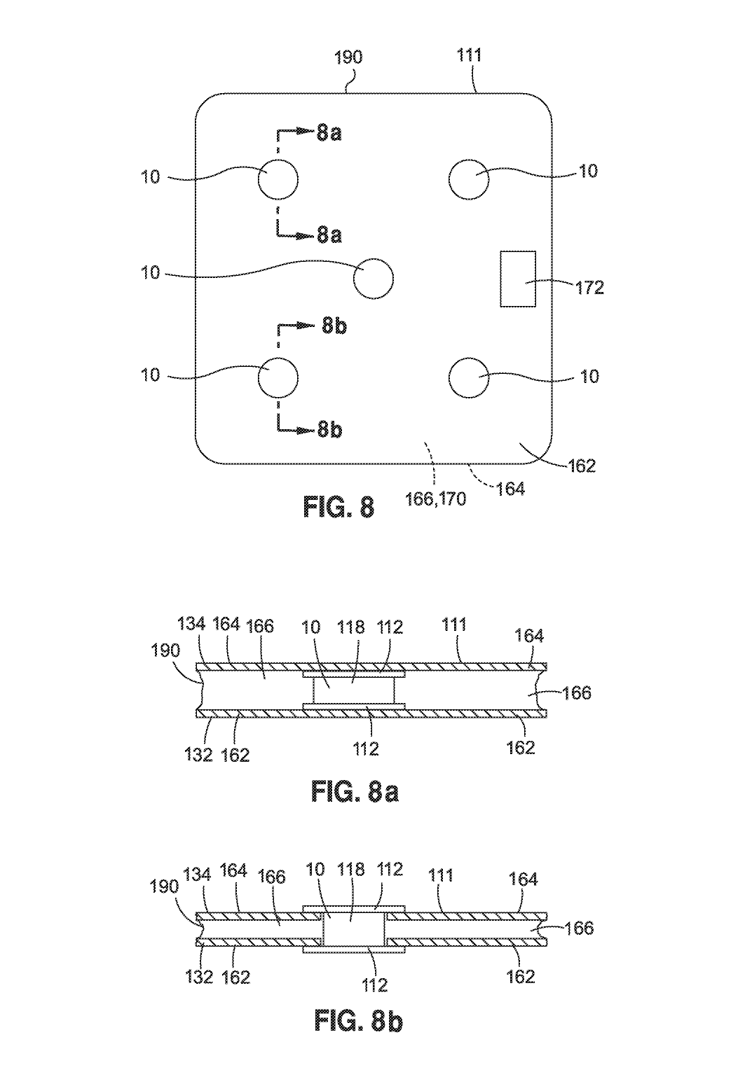

FIG. 8 is a plan view of a patch configuration of the wearable thermoelectric generator system 111 comprising a back pack 190 embodiment. The back pack 190 embodiment may be configured to be worn against the back of a wearer and may be sized to cover a relatively large area. However, the back pack 190 embodiment may be configured to be applied or worn at any location on the body 148 of a wearer and is not limited to being worn against a back of the wearer. For example, the patch configuration may comprise a patch (not shown) that is configured to be worn against a chest of the wearer. In FIG. 8, the back pack 190 embodiment may include multiple thermoelectric generators 10 which may optionally include heat couple plates 112. The thermoelectric generators 10 may be positioned between inner and outer material layers 162, 164 and may be arranged thermally in parallel and electrically in series and/or in parallel depending on power requirements of the device to be powered.

In the back pack 190 embodiment or in any other patch embodiment or band embodiment of the system 111 having multiple thermoelectric generators 10, the thermoelectric generators 10 may be provided as relatively small-sized thermoelectric generator 10 units that may be distributed across an energy harvesting area of the body. Advantageously, by distributing the thermoelectric generators 10, the thermal path from the heat source 146 (i.e., the body 148 core) via thermoelectric generators 10 to the heat exchanger 134 may be reduced. Advantageously, distributing a plurality of relatively small sized thermoelectric generators 10 may result in a reduction in the overall thickness or height of the system 111. In addition, thinner materials having less heat conducting capability may be used which may reduce the weight of the system 111. Thinner materials may also result in greater user comfort due to the conformability of the material to the wearer's body 148 and resulting in better form factor and improved aesthetics. The patch configuration may also be formed of graphite material and/or carbon fiber material formed as a flexible heat conductor having high thermal conductivity.

The density of the thermoelectric generators 10 per unit area may vary depending upon the quantity of locally available heat flow from the body 148 due to differences in thermal resistances for different areas of the body. For example, areas with increased blood circulation and/or near relatively large blood vessels may have a relatively low thermal resistance resulting in a higher heat flow and therefore may allow for a higher density of thermoelectric generators 10. Areas with reduced blood circulation and/or near relatively small blood vessels may have a relatively high thermal resistance resulting in a lower heat flow and therefore may dictate a lower density of thermoelectric generators 10.

FIG. 8a is a cross sectional view of the wearable thermoelectric generator system 111 of FIG. 8 and illustrating an arrangement for integrating an embodiment of the thermoelectric generator 10 into the system 111. As can be seen, the thermoelectric generator 10 may include heat couple plates 112. The heat couple plates 112 may be integrated into highly thermally conductive inner and outer material layers 162, 164. The inner and outer material layers 162, 164 may be formed of one or more of the materials disclosed herein for any of the above-described embodiments of the system 111 and may include metal mesh, metal-coated yarn, woven material, material containing ceramic fibers, and other materials mentioned above. The inner and outer material layers 162, 164 may be separated by a thermally insulating middle layer 166 as described above.

FIG. 8b is a cross sectional view of the wearable thermoelectric generator system 111 illustrating an additional arrangement for integrating a thermoelectric generator 10 into the system 111. As shown, the heat couple plates 112 may be configured to be directly exposed to the heat source 146 and the heat sink 152 which may result in reduced thermal resistance relative to the arrangement of FIG. 8a where the heat couple plates 112 are covered by the inner and outer material layers 162, 164. As can be seen, the configuration of the system 111 may be specifically adapted to achieve a desired thermal resistance that is compatible to the wearer and the environment 144.

FIG. 9 are perspective views of the thermoelectric generator 10 in various disc-shaped or button-shaped embodiments and which may be incorporated into any one of the embodiments of the system 111 disclosed herein. For example, one or more of the thermoelectric generator 10 embodiments may include solid tabs to facilitate attachment of the thermoelectric generator 10 to a layer of material of the wearable thermoelectric generator system 111. The tabs may include at least one hole to facilitate sewing the thermoelectric generator 10 into fabrics. Embodiments may include multiple tabs for crimping or sewing into fabrics or attachment to other materials that may be incorporated into the system 111. An embodiment may include wires 174 for electrical connection 188 to other thermoelectric generators 10 and/or to the electronics 172 module for power management. For limited space applications, an embodiment of the thermoelectric generator 10 may be provided without tabs and the thermoelectric generator 10 may be adhesively bonded in place or mechanically maintained in position due to insulative material surrounding the thermoelectric generator 10.

The thermoelectric generator 10 may be provided in a hybrid configuration for optimal integration of the thermoelectric generator 10 into the band configuration, the patch configuration, or other configuration. The patch configuration such as the back pack 190 embodiment may include a flexible or rigid material optionally having a pressure-sensitive adhesive on one side of the material. The rigid material may be a metallic material such as aluminum or steel or other metallic material or the rigid material may be a polymeric material such as plastic. The patch may also be provided as a flexible woven or non-woven material such as a fabric material. For example, the patch material may comprise a metallized material layer providing thermal conductivity from the wearer's skin to the thermoelectric generator. The pressure-sensitive adhesive may be configured for removably adhering the patch to the wearer's skin or to a fabric that may be covering the wearer's skin such as an article of clothing (e.g., an undergarment, a shirt, pants, a jacket, an over-garment, etc.) that may be worn by a wearer.

The thermoelectric generator 10 may be provided in a mushroom shape to facilitate bonding the thermoelectric generator 10 to a layer of material. In this regard, the mushroom shape may include one heat couple plate 112 that is larger than an opposite heat couple plate. The thermoelectric generator 10 may then be dropped into a preformed hole and glued and/or sewed into fabrics or other material. Any of the thermoelectric generator 10 embodiments disclosed herein may be electrically interconnected by means of wiring connected to the top and/or bottom sides which may have different polarities and may be electrically arranged in series.

In an embodiment, the system 111 may be provided in an embodiment wherein the thermoelectric generator 10 is configured to generate electricity when the function of the heat source and the heat sink are reversed. In this regard, the thermoelectric generator 10 may generate electricity when the heat source functions as the heat sink, and the heat sink functions as the heat source, which, in FIG. 2, may occur when the heat source 148 is at a lower temperature than the heat sink 152. For example, the heat source may include heating of the heat exchanger from the radiation of the sun to a higher temperature than the heat collector 132 contacting the cold skin of a wearer.

FIG. 10 is a block diagram of a power management system for the wearable thermoelectric generator system 111. The power management system is configured to regulate the operation of the system 111 to harvest a maximum amount of thermal energy in an efficient manner. During periods of high activity and when large thermal gradients exist across the system 111, the power management system will provide power directly to a capacitive bank for powering a regulated output voltage. During periods of low activity or when low thermal gradients exist across the system 111, a boost scavenges energy and store the energy into a thin film energy storage element.

Referring to FIGS. 11-18f wherein the reference numerals in FIGS. 11-18f correspond to the reference numerals contained in the description below, shown in FIG. 11 is a perspective view of an embodiment of a thermoelectric generator 10 having a generally square-shaped and being comprised of a rectangular array of foil segments 16 in a vertically stacked arrangement as described above. The embodiments shown in FIGS. 11-18f are the subject of U.S. Pat. No. 6,958,443 entitled LOW POWER THERMOELECTRIC GENERATOR filed on May 19, 2003, U.S. Pat. No. 7,629,531 entitled LOW POWER THERMOELECTRIC GENERATOR, and U.S. Pat. No. 8,269,096 entitled LOW POWER THERMOELECTRIC GENERATOR filed on Sep. 30, 2008, the entire contents of each one of the above-referenced patents being expressly incorporated by reference herein in their entirety.

FIG. 12 is a cross-sectional side view of the thermoelectric generator shown in FIG. 11 illustrating the arrangement of alternating n-type and p-type thermoelectric legs that are disposed on a substrate film of a series of foil segments as used in the thermoelectric generator disclosed herein. FIG. 3 is a schematic illustration of a typical p-type and n-type thermoelectric leg pair that makes up a thermocouple of a thermoelectric generator.

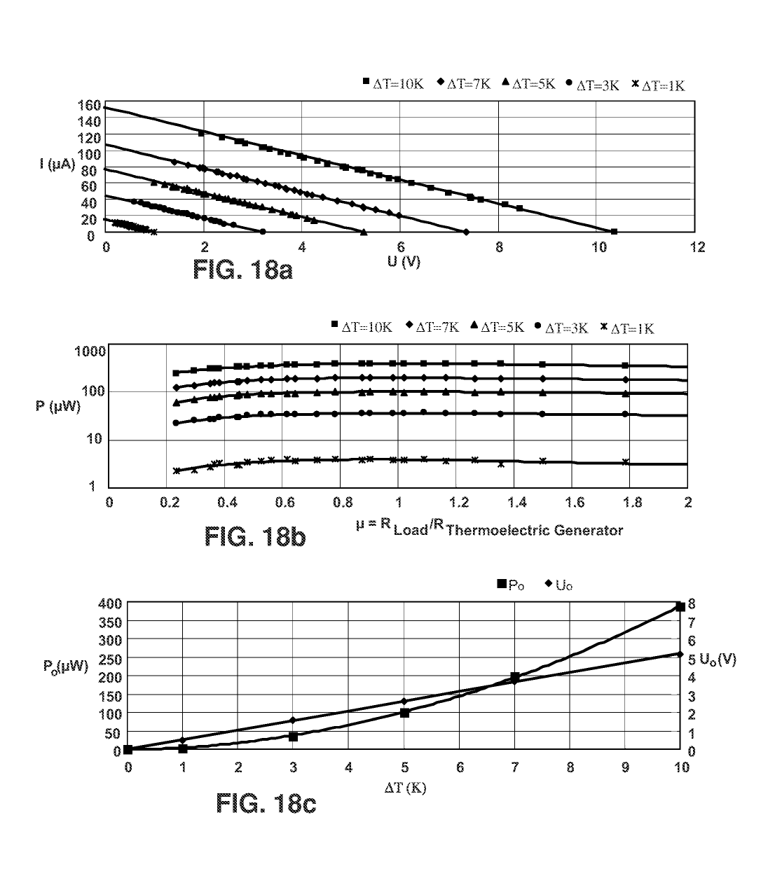

FIGS. 14a-17b illustrate the thermoelectric generator 10 in a further embodiment within which multiple foil segments 16 may joined end-to-end in a foil assembly 50 that is spirally wound into a circular shape. Importantly, such thermoelectric generator 10 achieves substantially greater power output than prior art thermoelectric generators due in part to a large reduction in electrical resistance, as will be described in greater detail below. As mentioned above, the thermoelectric generator 10 takes advantage of a thermal gradient to generate useful power under the Seebeck effect. FIGS. 18a-18f illustrate the improved power characteristics provided by the improved thermoelectric generator 10 under various temperature differences.

Referring still to FIGS. 14a-17b, the thermoelectric generator 10 may be comprised of a generally round or disc-shaped bottom plate 12, a generally round or disc-shape d top plate 14, and series of foil segments 16 connected end-to-end to form a single, elongate foil assembly 50. Alternatively, a unitary, elongate foil segment 16 may be spirally wound into a circular shape eliminating the need to connect individual foil segments 16 end-to-end. The spirally wound foil assembly 50 may include a hollow core 82 as a result of the manufacturing process. The hollow core 82 may be adapted for use as a cavity to contain electronic circuitry such as power management circuitry. The round shape of the thermoelectric generator 10 enhances its adaptability with certain devices such as wearable microelectronic devices. For example, the thermoelectric generator 10 may be easily adapted for use in a wrist-watch or a device generally shaped liked a wristwatch.

For the configuration of the thermoelectric generator 10 wherein the foil assembly 50 may be comprised of the series of foil segments 16, the foil assembly 50 is wound into the circular shape and then contained between the bottom plate 12 and the top plate 14. In this orientation, the foil assembly 50 and, hence, the foil segments 16 are perpendicularly disposed between and in thermal contact with the bottom and top plates 12, 14.

Each foil segment 16 is formed of an electrically non-conductive substrate 18 of preferably low thermal conductivity. A series of generally elongate, alternating n-type and p-type thermoelectric legs 32, 34 is disposed on a front substrate surface 40, back substrate surface 42, or both. As will be discussed in greater detail below, the thermoelectric legs 32, 34 are generally fabricated from a bismuth telluride-type thermoelectric material 44. The unique combination of material compositions for the substrate 18 and the thermoelectric material 44 provides a thermoelectric generator 10 having substantially improved power characteristics.

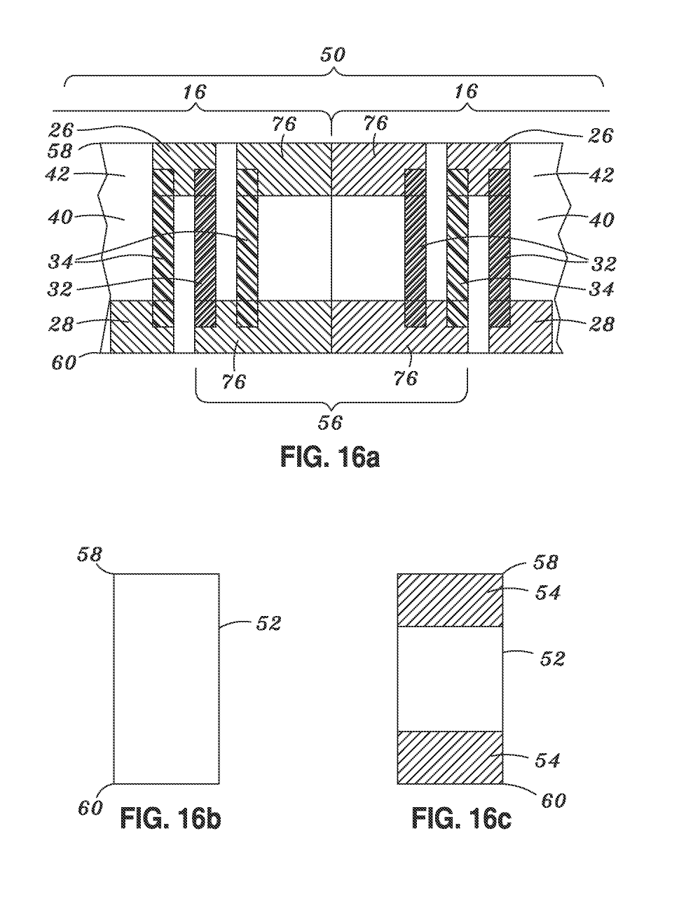

As may be seen in FIGS. 14b and 15b, the top plate 14 is disposed in spaced relation above the bottom plate 12. The bottom and top plates 12, 14 may have a generally circular or rounded shape. However, it will be recognized that the bottom and top plates 12, 14, which generally define the overall size of the thermoelectric generator 10, may be of any shape or configuration. In this regard, the generally rounded shape of the bottom and top plates 12, 14 may be easily adaptable for integrating the spirally wound series of foil segments 16. In one aspect, it is contemplated that the foil assembly 50 may be comprised of generally identically-configured foil segments 16 each having the same size and same arrangement of p-type and n-type thermoelectric legs 32 disposed thereupon. In this manner, the foil assembly 50 may be cost-effectively constructed of copies of foil segments 16 of the same size.

The bottom plate 12 and the top plate 14 may preferably be fabricated from any material that is substantially rigid and highly thermally conductive. For example, it is contemplated that metal and/or ceramic material may be utilized to fabricate the bottom and top plates 12, 14. The bottom plate 12 and top plate 14 may be configured to provide thermal contact between a heat sink 22 and a heat source 20, respectively, as can be seen in FIG. 11. The bottom and top plates 12, 14 are also configured to provide a protective housing such that the foil segments 16 are protected from mechanical contact and chemical influences. In this regard, sealant 70 may be provided on an outermost surface of the foil assembly 50 between the top and bottom plate 14, 12 such that the foil segments 16 are sealed against moisture, debris and other influences that may damage to or short-circuiting of the foil segments 16.

Referring now more particularly to FIGS. 14a to 17b, shown is the thermoelectric generator 10 having the foil assembly 50 captured between the disc-shaped top and bottom plates 14, 12. As can be seen in FIGS. 14a and 15a, the top and bottom plates 14, 12 may optionally include a perimeter flange 78 extending therearound. Such perimeter flange 78 may be intentionally provided or it may be the result of a manufacturing process wherein the top and bottom plates 14, 12 are manufactured in large quantity (i.e., high piece numbers) by utilizing common stamping and/or punching processes.

Such top and bottom plates 14, 12 may be stamped from thin metal material or metal foils and, as a result, may include a small edge burr (i.e., perimeter flange). Advantageously, the perimeter flange 78 may increase the stiffness and mechanical stability of the top and bottom plates 14, 12. Furthermore, the perimeter flange 78 may better contain the foil assembly 50 within the circumferential boundaries of the top and bottom plates 14, 12. Finally, the perimeter flange 78 may increase heat flow to and from the outermost portions of the foil assembly 50 at the location through metal bridges 26, 28 joining the pairs of n-type and p-type thermoelectric legs 32, 34 that are deposited on the foil assembly 50.

As was earlier mentioned, the top and bottom plates 14, 12 are preferably highly thermally conductive and, in this regard, act as heat couple plates in that their low thermal resistance preferably reduces thermal losses in thermoelectric generator 10. It is contemplated that the top and bottom plates 14, 12 may be fabricated of any suitable highly-thermally conductive material such as metal material including copper, aluminum, stainless steel, coated steel, and solderable metal alloys and various combinations thereof. Furthermore, the top and bottom plates 14, 12 may be fabricated of ceramic material which may optionally be combined with metal material. In this regard, ceramic may undergo a metallization process wherein a layer of metal is formed on a surface of the ceramic material. Depending upon the application of the thermoelectric generator, it may be desirable to increase the heat exchanging capabilities of at least one of the top and bottom plate. For example, at least one of the top and bottom plate may be provided with an enlarged surface area. Such enlarged surface area may be realized through the use of a cooling fin structure such that heat may be more readily dissipated or transferred to the surrounding environment.

Thin metal foils on the order of 50-250 microns (um) are preferably suitable as material for the top and bottom plates 14, 12 due to their low thermal resistance. Furthermore, such thin metal foil material may be easily converted into the top and bottom plates 14, 12 by simple manufacturing processes such as punching and stamping. As can be seen in FIG. 15b, at least one of the top and bottom plates 14, 12 may include a bore 80 passing therethrough and which may be centrally located and which may be utilized to enable integration or insertion of electronic circuitry within the hollow core 82 formed during the spiral-winding of the foil assembly 50.

Although configurable in any size, it is contemplated that the top and bottom plates 14, 12 may have a diameter in the range from about 4 millimeters (mm) to about 80 mm with a more preferable outer diameter of from about 5 mm to 25 mm and most preferably having an outer diameter of about 8 mm. The top and bottom plates 14, 12 are spaced apart to define an overall height of the thermoelectric generator 10 of between about 0.3 mm and about 4.0 mm dependant upon the overall height (i.e., width) of the substrate 18 material. More preferably, the height of the thermoelectric generator 10 is between about 0.5 mm to 2.0 mm and is most preferably about 1.0 mm in height.

It is contemplated that both the top and bottom plates 14, 12 may be utilized as electrical contacts by which the thermoelectric generator 10 may be connected to a device to supply power. In this regard, one end of the series of n-type and p-type thermoelectric legs 32, 34 connected in series is preferably electrically connected to the top plate 12 while an opposite end of the series of n-type and p-type thermoelectric legs 32, 34 is connected to the bottom plate 12. Such electrical connected may be facilitated through the use of electrical adhesive 64. However, bonding and/or soldering and other suitable electrically conductive means may be utilized to connect the top and bottom plates 14, 12 to respective ones of the opposite ends of the n-type and p-type thermoelectric legs 32, 34 on the foil assembly 50. If the top and bottom plates 14, 12 are fabricated of non-conductive materials such as ceramic material, a pair of first and second electrical leads 24, 30 may be connected to opposite ends of the thermocouple chain in a manner similar to that disclosed in U.S. Pat. No. 6,958,443 and which was mentioned above. However, the top and/or bottom plates may be configured as metallized ceramic plates to act as heat conductors as well as serve as electrical contacts for the thermoelectric generator.

Shown in FIG. 12 is a representative view of at least a portion of one of the foil segments 16 that make up the foil assembly 50 and illustrating the arrangement of the alternating n-type and p-type thermoelectric legs 32, 34 disposed on the substrate 18. As was earlier mentioned, each one of the foil segments 16 has a front substrate surface 40 and a back substrate surface 42 opposing the front substrate surface 40. Upon winding of the foil assembly 50 following end-to-end connection of the foil segments 16, the back substrate surfaces 42 faces the front substrate surface 40 of adjacent wraps of foil segment 16.

The spaced, alternating n-type and p-type thermoelectric legs 32, 34 are disposed parallel to each other on either or both of the front and back substrate surface 40, 42. To prevent short-circuiting, a cover layer 72 of standard, positive photoresist material may be deposited over the foil segment 16 following deposition of the n-type and p-type thermoelectric legs 32, 34. The cover layer may be provided following the metallization process used to create metal contacts and metal bridges, if included on the substrate 18. Although the thermoelectric material 44 may have a thickness in the range of from about 10 microns (μm) to about 100 μm, a preferable thickness of the n-type thermoelectric material 44 is about 15 μm.

Turning briefly now to FIG. 13, shown is a schematic representation of the n-type and p-type thermoelectric leg 32, 34 pair that makes up a thermocouple 46 of the thermoelectric generator 10. As can be seen in FIG. 13, the n-type and p-type thermoelectric legs 32, 34 have a respective width. The n-type thermoelectric leg 32 width is denoted as a₁. The p-type thermoelectric leg 34 width is denoted as a₂. The thermoelectric leg 32, 34 length for both the n-type thermoelectric leg 32 and the p-type thermoelectric leg 34 is denoted as b. Although the n-type and p-type thermoelectric legs 32, 34 may have substantially equal lengths, it is contemplated that the thermoelectric generator 10 may be configured wherein the n-type and p-type thermoelectric legs 32, 34 are of differing lengths. Advantageously, the extreme aspect ratio of the length to the width allows the generation of relatively high thermoelectric voltages in the miniaturized thermoelectric generator 10.

The geometry of the respective ones of the n-type and p-type thermoelectric legs 32, 34 may be adjusted to a certain extent depending on differences in electrical conductivities of each of the n-type and p-type thermoelectric legs 32, 34. The width of the thermoelectric legs 32, 34 may be in the range of from about 10 μm to about 100 μm. The lengths of the thermoelectric legs 32, 34 may be in the range of from about 100 μm to about 500 μm. A preferred length b of the n-type and p-type thermoelectric legs 32, 34 is about 500 μm. A preferred width a₁ of the n-type thermoelectric leg 32 is about 60 μm while a preferred width a₂ of the p-type thermoelectric leg 34 is about 40 μm. The thermoelectric properties of the p-type thermoelectric leg 34 are typically superior to those of the n-type thermoelectric leg 32. Therefore, the width of the p-type thermoelectric legs 34 can be narrower than that of the n-type thermoelectric legs 32. Although the thermoelectric legs 32, 34 are shown in FIG. 12 as having an elongate configuration, it is contemplated that the thermoelectric legs 32, 34 may configured in numerous other configurations such as, for example, an L-shaped or S-shaped configuration.

The n-type and p-type thermoelectric legs 32, 34 are connected thermally in parallel and electrically in series. As illustrated schematically in FIG. 12, each one of the p-type thermoelectric legs 34 is electrically connected to an adjacent one of the n-type thermoelectric legs 32 at opposite ends of the p-type thermoelectric legs 34 by a hot side metal bridge 26 and a cold side metal bridge 28. In this manner, electrical current may flow through the thermoelectric legs 32, 34 from a bottom to a top of a p-type thermoelectric leg 34 and from a top to a bottom of an n-type thermoelectric leg 32. Each alternating one of the thermoelectric legs 32, 34 is connected to an adjacent one of the thermoelectric legs 32, 34 of opposite conductivity type, forming a thermocouple 46.

In FIG. 13, the representative n-type thermoelectric leg 32 is connected at a respective upper end thereof to a respective upper end of the p-type thermoelectric leg 34. In FIG. 12, a plurality of n-type and p-type thermoelectric legs 32, 34 are connected at opposite ends thereof forming a plurality of thermocouples 46 and leaving a free p-type thermoelectric leg 34 and a free n-type thermoelectric leg 32 on extreme opposite ends of each of the foil segments 16. Whenever heat is applied by the heat source 20 through the top plate 14 at the hot side metal bridge 26, a temperature gradient, indicated by the symbol AT, is created with respect to the cold side metal bridge 28 of the thermocouple 46 at the bottom plate 12 and heat sink 22 such that a heat flux 48 flows through the thermoelectric generator 10. Current then flows through a load in the electrical circuit 36 in the direction indicated by the symbol A. The thermoelectric generator 10 may further comprise a first electrical lead 24 and a second electrical lead 30 respectively connected to opposite ends of the series of n-type and p-type thermoelectric legs 32, 34 in the case where the top and bottom plate 14, 12 do not also serve as electrical contacts for the thermoelectric generator 10.

Each one of the hot side metal bridges 26 and cold side metal bridges 28 is configured to electrically connect an n-type thermoelectric leg 32 to a p-type thermoelectric leg 34. Each one of the hot side metal bridges 26 and cold side metal bridges 28 is also configured to act as a diffusion barrier in order to impede the diffusion of unwanted elements into the n-type and p-type thermoelectric legs 32, 34 which may be easily contaminated with foreign material. Furthermore, each one of the hot side metal bridges 26 and cold side metal bridges 28 is configured to impede the diffusion of unwanted elements out of the n-type and p-type thermoelectric legs 32, 34. Finally, each one of the hot side metal bridges 26 and cold side metal bridges 28 is configured to conduct heat into and out of the p-type and n-type thermoelectric legs 32, 34. In this regard, the hot side metal bridges 26 and cold side metal bridges 28 may be fabricated of a highly thermally conductive material such as gold-plated nickel.

In the illustration shown in FIGS. 12, 16a and 17a, the first electrical lead 24 is connected to a free end of the n-type thermoelectric leg 32 while the second electrical lead 30 is connected to a free end of the p-type thermoelectric leg 34. However, for the thermoelectric generator 10 having an array of foil segments 16 disposed in side-by-side arrangement as shown in FIG. 11, the foil segments 16 are electrically connected in series such that a free one of the n-type thermoelectric legs 32 on an extreme end of the foil segment 16 is electrically connected to a free one of the p-type thermoelectric legs 34 of an adjacent one of the foil segments 16, and vice versa. In such a configuration, the first electrical lead 24 is connected to a free end of the n-type thermoelectric leg 32 of a forward-most foil segment 16 of the array while the second electrical lead 30 is connected to a free end of the p-type thermoelectric leg 34 of the aft-most foil segment 16 of the array.

It is contemplated that the plurality of foil segments 16 of the foil assembly 50 may preferably include a total of about 5000 thermocouples 46 substantially evenly distributed on the array of foil segments 16 although it is contemplated that the thermoelectric generator 10 may comprise any number of thermocouples 46 from about 1000 to about 20,000. In the embodiment shown in FIG. 6a, a total of 5265 thermocouples 46 may be provided to account for the reduction in the quantity of effective thermocouples 46 due to electrical redundancy of the end-to-end connection between foil segments 16, as will be described in greater detail below.

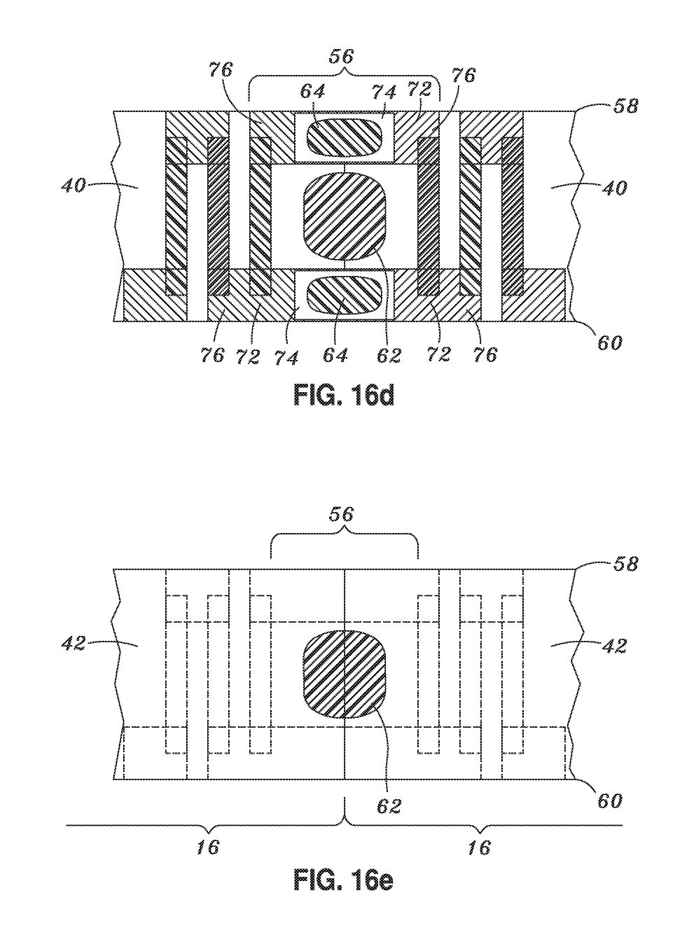

In one embodiment, the thermoelectric generator 10 may include about nineteen (19) of the foil segments 16 connected end-to-end to create a foil assembly 50 having an overall length of about 1 meter. Alternatively, however, the thermoelectric generator 10 may include any number of foil segments 16 sufficient to integrate the total number of thermocouples 46 needed for producing the required power at the given operating temperatures. Assuming that all the thermocouples 46 are electrically connected in series, the total voltage output of the thermoelectric generator 10 is simply calculated as the sum of the individual voltages generated across each thermocouple 46, accounting for non-contributing thermocouples 46 as part of the electrically redundant connection type shown in FIG. 16a.

In a preferred embodiment, the substrate 18 has a thickness in the range of from about 7.5 μm to about 50 μm, although the thickness of the substrate 18 is preferably about 25 μm. Because of the desire to reduce the thermal heat flux 48 through the substrate 18 in order to increase the efficiency of energy conversion, it is desirable to decrease the thickness of the substrate 18 upon which the thermoelectric legs 32, 34 are disposed. Regarding the material that may comprise the substrate 18, an electrically insulating material may be utilized such that the adjacent ones of the thermoelectric legs 32, 34 disposed on the substrate 18 may be electrically insulated from one another.

The substrate 18 material may also have a low thermal conductivity and may be a polyimide film such as Kapton film made by DuPont. Due to its low thermal conductivity, polyimide film is an excellent substrate 18 for thermoelectric generators 10. In addition, polyimide film has a coefficient of thermal expansion that is within the same order of magnitude as that of the bismuth telluride-type material utilized in the thermoelectric legs 32, 34 in the room temperature range of about 70° F. Therefore, by utilizing polyimide film, the residual mechanical stresses that may occur at the substrate 18/thermoelectric material 44 interface may be minimized or eliminated. In this regard, the overall durability and useful life of the thermoelectric generator 10 may be enhanced.

The thermoelectric material 44 that makes up the n-type and p-type thermoelectric legs 32, 34 may be comprised of a semiconductor compound of the bismuth telluride (Bi₂Te₃) type, as was mentioned above. However, the specific compositions of the semiconductor compound may be altered to enhance the thermoelectric performance of the n-type and p-type thermoelectric leg 32, 34. In this regard, the semiconductor compound utilized as a starting material in depositing, such as by sputtering, of the p-type thermoelectric legs 34 32 may comprise a material having the formula:

(Bi_{0.15}Sb_{0.85})_{2Te3} plus 18 at. % Te excess,

although the excess may be in the range of from about 10 at. % Te excess to about 30 at. % Te excess.

The semiconductor compound (i.e., the starting material or target material) utilized in fabricating the n-type thermoelectric legs 32 via sputtering may preferably comprise a material having the formula:

Bi₂(Te_{0.9}Se_{0.1})₃ plus about 22 at. % (Te_{0.9}Se_{0.1}) excess,

although the excess may be anywhere within the range of from about 10 at. % (Te_{0.9}Se_{0.1}) excess to about 30 at. % (Te_{0.9}Se_{0.1}) excess. It should be noted that the above-recited compositions or formulae for the p-type and n-type thermoelectric material 44s are in relation to the initial or starting material from which sputtering targets are fabricated. In the fabrication method disclosed herein, the thermoelectric material 44 for the n-type and p-type legs is the starting material prior to the sputtering operation. The stoichiometric composition of the thermoelectric material 44 as disclosed herein advantageously results in a relatively high thermoelectric figure of merit (Z).

Although a number of different microfabrication techniques may be utilized in depositing the thermoelectric material 44 onto the substrate 18, the method of sputtering, such as magnetron or plasmatron sputtering, may preferably be utilized with the aid of high vacuum deposition equipment. Sputtering may be utilized for deposition of relatively thick bismuth telluride-based thermoelectric material 44 onto the thin substrates 18. When used in conjunction with the material system described above, significantly high power output is achievable with the thermoelectric generators 10 of the present disclosure. Such increased power output is due in part to the use of bismuth telluride-type material systems which have a relatively high figure of merit (Z) compared to other material systems in the room temperature range and which effectively operate in a range of from about 32° F. to about 212° F. (i.e., equivalent to a range of about 0° C. to about 100° C.).

As was earlier mentioned, the efficiency of thermoelectric generators 10 may be characterized by a thermoelectric figure of merit (Z), defined by the formula: Z=S²σ/κ, where σ and κ are the electrical conductivity and thermal conductivity, respectively, and where S is the Seebeck coefficient expressed in microvolts per degree (μV/K). Z can be rewritten as P/κ where P is the power factor. In the thermocouple 46 arrangement of the thermoelectric generator 10 disclosed herein disclosure, the direction of heat flow through the thermoelectric legs is parallel to the direction of heat flow through the substrate 18. Therefore, it may be preferable to consider the power factor as a measure of the effectiveness of the thermoelectric material 44.

Due to the unique material compositions of the thermoelectric legs of the present disclosure in combination with the deposition procedure, relatively high values for the power factor (P) of the thermoelectric material 44 were achieved. For example, it was discovered that depositing the Bi₂Te₃-type thermoelectric material 44 onto the substrate 18 by sputtering resulted in improved values for the power factor for both the p-type and n-type thermoelectric material 44 as compared to prior art arrangements.

More specifically, it was discovered that using the optimized sputtering procedure for the p-type Bi₂Te₃-type thermoelectric material 44, the Seebeck coefficient (Sₚ) was about 210 μV/K while the electrical conductivity (σₚ) was about 800 1/(Ω*cm) for a power factor (Pₚ) of about 35 μW/(K²*cm) in the room temperature range. For the n-type Bi₂Te₃-type thermoelectric material 44, the Seebeck coefficient (Sₙ) was about 180 μV/K while the electrical conductivity (σₙ) was about 700 1/(Ω*cm) for a power factor (Pₙ) of about 23 μW/(K²*cm) in the room temperature range. It should be noted that the thickness of the n-type thermoelectric leg 32 for the above-mentioned results was about 15 μm.

For the thermoelectric generator 10 having the above-noted mechanical and electrical properties, improvements in power output are realized and are documented in FIGS. 18a-18f. For example, for a temperature differential between the top and bottom plates 14, 12 of about 5K, open-circuit voltage output may be in the range of from about 4.0 V and about 6.5V with a measured value of about 5.2V. Likewise, short-circuit current output may be in the range of from about 60 μA and about 100 μA with a measured value of about 76 μA. The electrical power output in the case of a matched load for a preferred embodiment of the thermoelectric generator 10 is contemplated to be in the range of from about 70 μW and about 130 μW at a temperature differential between the top and bottom plates 14, 12 of about 5K and at a voltage of between about 2.0V to about 3.5V with a measure value of about 2.6V.

More particularly, as can be seen in FIGS. 18a-18f, power characteristics and electric parameters for the thermoelectric generator 10 vary according to the temperature differential between the top plate 14 and the bottom plate 14, 12. For example, FIGS. 18a and 18d are plots of electrical parameters of the thermoelectric generator 10 for various temperature differentials between the top and bottom plates 14, 12. More specifically, FIGS. 18a and 18d are plots of voltage in volts versus electrical current measured in microamps. As can be seen in FIG. 18a, the thermoelectric generator 10 provides an open circuit voltage of 5.2 volts and a short circuit electrical current output of 76.5 microamps (μA)at a temperature gradient of 5 K.

FIGS. 18b and 18e are plots of power output in the case of a matched load indicated on the plot as a ratio of resistance of a load over resistance of the thermoelectric generator 10. As can be seen in FIG. 18b, for the case or in the ratio of the resistance of the load to the resistance of the thermoelectric generator 10 is approximately 1, the electrical power output is almost 100 microwatts (μW) at a temperature differential of 5 K across the top and bottom plates 14, 12. Referring to FIGS. 18c and 18f, shown are plots of power output of the thermoelectric generator 10 at a match load (i.e., ratio of resistance of load to resistance of the thermoelectric generator 10 equals 1) to temperature difference across the top and bottom plates 14, 12. As can be seen in FIG. 18c, the thermoelectric generator 10 provides a voltage output of 2.6 volts at a temperature gradient of 5 K and a power output of 100 μl W at such matched load. Such measurements as referenced in FIGS. 18a and 18f are taken at basic temperatures of 30° C. Furthermore, as can be seen by reference to 8c, both the power output and the voltage output of the thermoelectric generator 10 generally increase with the corresponding increase in the temperature gradient across the top and bottom plates 14, 12.

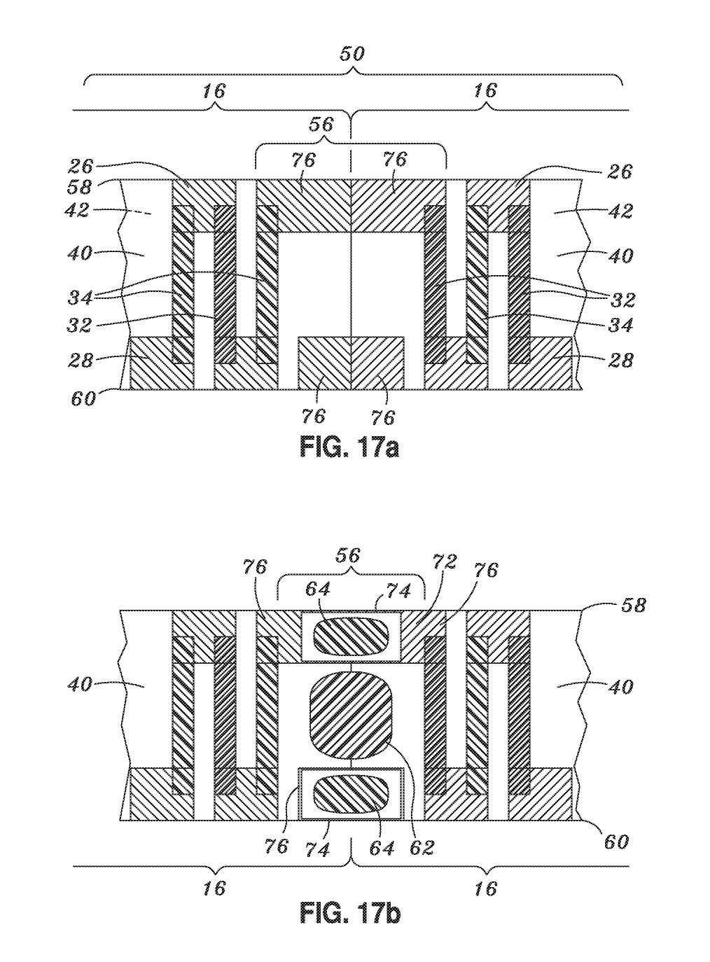

Referring now more particularly to FIGS. 16a to 17b, shown are several embodiments by which the end-to-end foil segments 16 may be mechanically and electrically connected. As was earlier mentioned, the foil assembly 50 may be comprised of a plurality of foil segments 16 disposed end-to-end mechanically and electrically connected to one another. Although the thermoelectric legs may be deposited on either one of the front or back substrate surfaces 40, 42 or on both of the substrate 18 surfaces, depositing on only the front substrate surface 40 may be advantageous in that the thermoelectric legs may be disposed in an inward direction when spirally wound which results in a lower thermo-mechanical tension on an inner side of the substrate 18 system.

Conversely, because the thermoelectric legs are deposited on the substrate 18 while the substrate 18 is in a flat or planar orientation followed by subsequent winding of the substrate 18 into a round package, relatively high mechanical stresses develop on an outer side (i.e., back substrate surface) as opposed to the mechanical forces generated on the inside (i.e., front substrate surface) of the foil segment 16 upon winding. Short circuiting between the wraps of the foil assembly 50 is prevented by providing a cover layer 72 on both sides of the stripes following deposition of the thermoelectric legs, as will be described in greater detail below.

The winding of the foil assembly 50 may include the creation of the hollow core 82 at a center thereof. It is contemplated that a minimum diameter for winding of the foil assembly 50 is about 1 mm which equates to an inner diameter of the hollow core 82. However, should the thermoelectric generator 10 be configured to contain or enclose certain components such as electronic circuitry, then the hollow core 82 may be enlarged to provide up to about 80 mm (e.g., size of a wristwatch or similar device) such that the foil assembly 50 is provided in more of a ring shape or doughnut shape.

Referring still to FIGS. 16a to 17b, end-to-end connection of the adjacent ones of the foil segments 16 may be facilitated through the use of a plurality of connectors 52 in the foil assembly 50. Each one of the connectors 52 may act as a splice across the joint between the adjacent foil segments 16 and, in this regard, may be disposed against at least one of the front and back substrate surfaces 40, 42. As was earlier mentioned, such additional mechanical stability is provided by bonding a connector to both the front and back substrate surfaces. The connectors 52 are configured to at least mechanically connect free ends of adjacent ones of the foil segments 16.

As can be seen in FIG. 16b, a connector 52 for purely mechanical connection of the back substrate surface and front substrate surface of end-to-end foil segments 16 is shown. Although the substrate 18 may include thermoelectric legs on both the front and back substrate surfaces 40, 42, if the back substrate surface 42 is void of thermoelectric legs, bonding of the connector 52 such as that shown in FIG. 16b is facilitated through the use of an assembly adhesive 62 which is preferably non-electrically conductive and of low thermal conductivity. Such assembly adhesive 62 is preferably UV or visible-light curable adhesive such as an epoxy or an acrylate glue. However, any suitable non-electrically conductive adhesive with low thermal conductivity and the proper mechanical parameters may be utilized.

It is contemplated that the connectors 52 are fabricated of polyester foil or other suitable material which is of low thermal conductivity and which is also electrically non-conductive. The connector 52 may be fabricated of UV-transparent polyester foil material. The sizing of the connector 52 is preferably such that the connector 52 has a relatively small length which is measured from side-to-side as shown in FIGS. 16b and 6c. Such small length is desirable in the connector in order to reduce parasitic heat flux 48. However, mechanical stability between the foil segments 16 is enhanced through the use of a longer connector 52. An exemplary length of one of the connector 52 for bonding to the back substrate surface 42 is about 1500 μm although the connector 52 may be provided in any length. The connector 52 may be fabricated of polyester foil material having a thickness which is preferably less than that of the substrate 18 and more preferably which is about 12 μm.

Bonding of the connector 52 via the assembly adhesive 62 may be facilitated by pre-treatment of at least one side of the connector 52 in order to increase adhesion of the connector 52 to the assembly and electrical adhesive as well as to increase the adhesion between metal contacts 54 and the connector 52. Such metal contacts 54 are for electrically connecting the foil segments 16, as will be described in greater detail below. The connectors 52 are preferably of a height generally equivalent to that of the substrate 18 in order to facilitate interconnection between the foil segments 16. As can be seen in FIG. 16b, metal contacts 54 may be omitted from the connector 52 which is preferably installed on a side of the substrate 18 lacking thermoelectric legs. FIG. 16c illustrates a location and configuration of metal contact 54 which facilitates electrically connecting the thermoelectric legs.

Referring to FIG. 16c, shown is the connector 52 having the metal contacts 54 disposed thereupon. Such metal contacts 54 are preferably of a thickness within the range of one (1) μm to about five (5) μm nickel and may be covered by a thin (e.g., 100 nanometers (nm)) layer of gold which may be deposited by appropriate thin film (i.e., sputtering, thermal evaporation, etc.) processes or by thick film processes.

Referring now to FIGS. 16a and 17a, shown are adjacently disposed free ends of the foil segments 16 to be joined. In addition to the alternation n-type and p-type thermoelectric legs 32, 34 disposed on the substrate 18, the end contacts 76 are preferably included along top and bottom edges 58, 60 of the substrate 18 in order to provide a means for connecting the endmost ones of the n-type and p-type thermoelectric legs 32, 34 in each foil segment 16. In this regard, the end contact 76 provides a means for electrically connecting at least one of the n-type and p-type thermoelectric legs 32, 34 disposed adjacent the free ends of each of the foil segments 16.

The connectors 52 may be then used to provide a conductive path across the abutting end contacts 76 of the adjacent foil segments 16. In this regard, the metal contacts 54 may be similar in size to the hot side and cold side metal bridges 26, 28 that are used for interconnecting the n-type and p-type thermoelectric legs 32, 34 along the foil segments 16. The metal contacts 54 are sized and configured to electrically connect an endmost one of the n-type thermoelectric legs 32 of one of the foil segments 16 to an endmost one of the p-type thermoelectric legs 34 of an adjacent one of the foil segments 16. Such an arrangement is illustrated in FIG. 17a wherein the leftmost foil segment 16 includes a metal bridge at the top edge 58 connected to a p-type thermoelectric leg.

In FIG. 17a, the rightmost foil segment 16 includes a metal bridge at a top edge 58 of the foil segment 16 connecting the n-type thermoelectric leg 32. In addition, the bottom edge 60 of each one of the foil segments 16 includes the cold side metal bridge 28 which is not connected to any of the n-type or p-type thermoelectric legs 32, 34 but which is provided to balance the mechanical forces and create a symmetry of thickness between the top and bottom edges 58, 60 of the foil assembly 50 at the foil joints 56. Such symmetry thickness facilitates bonding of connectors 52 to the foil segments at the foil joint 56.

Referring briefly now to FIG. 17b, shown is a preferred embodiment for bonding of the connector 52 to the foil segment 16 in order to provide mechanical and electrical connection therebetween. More specifically, FIG. 17b illustrates a layer of assembly adhesive 62 disposed between the end contacts 76 of the top and bottom edges 58, 60, respectively. Such assembly adhesive 62 is preferably of low thermal conductivity and electrically non-conductive and is adapted to bond a middle portion of the connector 52 to at least one of the front and back substrate surfaces 40, 42 in order to mechanically connect the free ends of the adjacent foil segments 16. At the top and bottom edges 58, 60 along the end contacts 76 is a layer of electrical adhesive 64 which is preferably thermally low-conductive and which is configured to bond the metal contacts 54 at top and bottom edges 58, 60 of the connector 52 to respective ones of the end contacts 76 of the adjoining foil segments 16. Such electrical adhesive 64 is preferably UV or visible-light curable adhesive such as an epoxy or an acrylate glue. However, any suitable electrically conductive adhesive may be utilized with the proper mechanical parameters.

The configuration shown in FIG. 17b provides a method for simply connecting the endmost ones of the n-type and p-type thermoelectric legs 32, 34 electrically in series. However, in the interest of providing a redundancy in order to prevent failure of the thermoelectric device in the event of a poor electrical connection between both foil segments, an alterative joint configuration is shown in FIGS. 16a and 6d which increases redundancy of the electrical contact between the adjacent foil segments 16. More specifically, the joint configuration shown in FIG. 6a provides that the end contact 76 extends along at least one of the top and bottom edges 58, 60 adjacent to the free end of the foil segment 16.

The end contact 76 is preferably electrically connected to one of the n-type thermoelectric legs 32 and one of the p-type thermoelectric legs 34 which is disposed nearest the free end of the foil segment 16. Upon application of the connector 52 configuration shown in FIG. 16c, using the above described application of assembly and electrical adhesives 64, at least one of the metal contacts 54 is configured to electrically connect an endmost pair of n-type and p-type thermoelectric legs 32, 34 of the leftmost foil segment 16 to an endmost pair of n-type and p-type thermoelectric legs 32, 34 of the right hand foil segment 16. Referring briefly to FIG. 16d, shown is the pattern by which the assembly and electrical adhesive 64 may be applied which is similar to that which is shown in FIG. 7b for the singly-redundant version of the foil joint 56.

Referring briefly to FIGS. 16d and 17b, shown therein are openings or windows 74 in the cover layer 72. As was earlier mentioned, the cover layer 72 is applied over the thermoelectric legs and substrate 18 following the deposition process. Such windows 74 may be created by appropriate masking or other suitable manufacturing step in order to locally eliminate the electrically non-conductive cover layer 72. The cover layer 72 is primarily intended to prevent electrical contact between successive wraps of the foil assembly 50 when spirally wound. Also, the cover layer 72 provides mechanical stabilization of the thermoelectric legs, protects against oxidation and corrosion, and limits chemical contact, etc. As can be seen in FIGS. 16d and 17b, such windows 74 may be configured to be slightly smaller than the size of the metal contact 54 of the connector 52 to which the end contacts 76 are to be electrically bonded.

For example, if the end contacts 76 and/or metal contacts 54 have a height of about 150 μm, it is contemplated that the windows 74 in the cover layer 72 over the end contacts 76 is about 120 μm in height. In this same regard, the window 74 may have a length of about 220 μm which is compatible to a length of the metal contacts 54 of the connectors 52. Regarding the general length of the connector 52, any suitable dimension can be provided but may preferably be about 500 μm for the connectors 52 having the metal contacts 54 deposited thereupon. As was earlier mentioned, the length of the connector 52 mounted on the back substrate surface 42 (i.e., which may lack thermoelectric legs) may be generally longer and may be on the order of about 1500 μm.

Referring back to FIGS. 14a and 15a, shown is a cross-sectional view of the thermoelectric generator 10 illustrating the wraps of foil segments 16 encapsulated between the top and bottom plates 14, 12. As was earlier mentioned, winding of the foil assembly 50 into the round package results in the generation of the hollow core 82 which is preferably filled with an electrically non-conductive filler 68 of low thermo conductance. Such filler 68 may act to prevent the creation of mechanical forces due to pressure differential created between the inside of the hollow core 82 and outside of the top and bottom plates 14, 12. Alternatively, FIG. 15a shows a bore 80 formed in at least one of the top and bottom plates 14, 12 to facilitate insertion of electronic circuitry or any other suitable components.

In the configuration shown in FIG. 15a, the electronic circuitry may be first inserted into the hollow core 82 and then filled with filler 68. Sealant 70 may also be provided on a perimeter of the hollow core 82 to prevent electrical and thermal conductance to the foil assembly 50. The filler 68 may be comprised of any suitable material and is preferably material having low thermal conductivity such as elastic or non-elastic material including adhesives and/or foams, hollow glass spheres (e.g., microballoons) or any mixture or combination thereof.

Regarding the electronic circuitry, such may be integrated into the thermoelectric generator 10 and may also be powered thereby to represent a portion of or a complete solution to an electronic power management system for a final electronic application of the thermoelectric generator 10. It is further contemplated that the spirally wound foil assembly 50 may form a ring around the electronic circuitry. In this manner, the overall size of the electronic circuitry is determinative of the minimum inner diameter of the hollow core 82. However, it is contemplated that additional electronic components which also form part of the electronic circuitry but which cannot be placed inside the hollow core 82 can instead be disposed and arranged outside of the thermoelectric generator 10 as a separate unit and may be mountable on the top and/or bottom plate 14, 12. In addition, a thin film battery may be deposited inside of at least one of the top and bottom plates 14, 12. In this manner, the top and bottom plates 14, 12 may act as a substrate for the thin film battery which may be adapted to fit within the hollow core 82. Alternatively, the thin film battery may be configured to extend across any or all portions of at least one of the top and bottom plates 14, 12.

Such electronic circuitry may comprise an electronic low power management system and/or the final electronic application and may include various devices such as a wristwatch, pulse/blood pressure meter and other medical devices, RFID devices, as well as sensor devices which may also be provided in RF technology format. Electronic circuitry in the form of power management systems may be integrated in order to process power generated by the thermoelectric generator 10 and also to provide a stable and buffered power source for the final electronic application. Ideally, the power management system itself should consume as little power as possible and may comprise the following features: excess voltage protection, energy storage, protection against reverse thermoelectric voltages and reverse electric currents, a rectifier to convert reverse thermoelectric voltages, low voltage protection for the electronic application, and energy storage management for the electronic application (i.e., wristwatch).

Excess voltage protection may be facilitated by means such as a diode or series of diodes connected in a forward direction and parallel to the final electronic application. Energy storage may be facilitated by means of various electronic components including a capacitor (low leakage, high capacity types and super capacitor types), or a rechargeable thin film battery or a combination of both devices. Protection against reverse voltages may be facilitated through the use of a diode having a low forward voltage, such as a Schottky diode, connected in a forward direction and in series with the thermoelectric generator 10.

The rectifier may be provided to convert reverse voltages and may be facilitated by the use of various components such as, for example, a Graetz-Bridge (e.g., an arrangement of four diodes) such that reverse thermoelectric voltages may be used to power certain electronic. In addition, the rectifier may facilitate blocking of reverse electric currents generated by an electronic low power management system and/or by the final electronic application.

Low voltage protection of the final electronic application may be facilitated through the use of a comparator circuit. Such comparator circuit may be configured to interrupt power produced by the thermoelectric generator 10 if an operating voltage of the final electronic application drops below a threshold voltage. Energy storage management may be critical for optimal usage of the thermoelectric generator 10. In this regard, it is desirable to configure such an energy storage management system such that power may be provided by the thermoelectric generator 10 when needed but energy may also be stored to prevent wasting of excess energy. It is contemplated that such energy storage management may be realized using an electronic circuit which provides energy in a storage capacity depending upon the voltage level requirements. Parts or the entire circuitry of an electronic low power management system may be facilitated as ASIC (i.e., Application-Specific Integrated Circuit) for enhancement of integration density and functionality and for reduction of power consumption.

Referring still to FIGS. 14a and 15a, the thermoelectric generator 10 may include a layer of sealant 70 extending around an outer circumferential portion of the foil segment 16 between the top and bottom plates 14, 12. Such sealant 70 is preferably electrically non-conductive and of low thermal conductance. Such sealant 70 is preferably configured to increase protection of the thermoelectric generator 10 against moisture absorption, corrosion, fluid contamination, debris as well as sealing against other undesirable elements. The sealant 70 may be applied to an outer area of the foil assembly 50 and also additionally in the hollow core 82 area as well to fill the bore 80 in any of the top or bottom plates 14, 12.

In manufacturing the thermoelectric generator 10 of the present disclosure, an initial step may include substrate 18 preparation and may comprise cutting the substrate 18 into the appropriately-sized pieces, followed by an annealing process and gluing of the substrate 18 onto frames for support thereon. Such substrate 18 may be any suitable material and is preferably Kapton Tape. After framing of the substrate 18 and following the annealing process, the p-type thermoelectric material 44 is deposited onto the substrate 18.

Such deposition step comprises preparation of a vacuum chamber and plasma etcher and insertion of target and wafer holders into the vacuum chamber. As was earlier mentioned, such p-type thermoelectric material 44 is preferably of the bismuth-telluride type with the above-described amounts of excess Te. Following plasma dry-etching, cold sputtering of the p-type thermoelectric material 44 is performed at room temperature. Hot sputtering is then performed in order to increase crystal growth of the p-type thermoelectric material 44. The hot and cold sputtering processes may be alternated any number of times (preferably three times each) in order to provide an optimal power factor for the deposited thermoelectric material 44. Following deposition of the p-type thermoelectric material 44, the photolithography of same is performed by application and structuring of photo resist. The p-type thermoelectric material 44 is then structured by etching followed by stripping of the photo resist.

Deposition of n-type thermoelectric material 44 is then performed in the vacuum chamber with a plasma etcher using targets of the appropriate bismuth-telluride material As was earlier mentioned, such n-type thermoelectric material 44 is preferably of the bismuth-telluride type with the above-described amounts of excess Te and Se. Alternating cold and hot sputtering may also be performed in order to provide an optimal layer of n-type thermoelectric material 44. Following photolithography and structuring by etching of the n-type thermoelectric material 44, lift-off photolithography is then performed followed by deposition of the nickel-gold layer for the hot and cold metal bridges 26, 28, the end contacts 76 of the foil segments 16, and the metal contacts 54 of the connectors 52. Following lift-off structuring, photolithography to generate the cover layer 72, annealing, and cutting of the wafer into foil segments 16, the foil segments 16 may be assembled end-to-end.

The foil segment assembly process may be initiated with the adhesion of the connector 52 similar to that shown in FIG. 6b to at least one of the front and the back substrate surfaces 40, 42 using assembly adhesive 62 in the location shown in FIG. 16e. Mechanical and electrical connection of the foil segments 16 may then be performed by adhering the connector 52 shown as configured in FIG. 16c to the front substrate surface 40 wherein electrical adhesive 64 is applied to span between the endmost ones of the n-type and p-type thermoelectric legs of adjacently disposed foil segments. Alternatively, if end contacts 76 and metal contacts 54 are provided on the foil segments in the patterns shown in FIGS. 16d and 17b, electrical adhesive 64 may be applied to bond the metal contacts to at least one of the end contacts of one of the foil segments to improve the electrical connection. Such electrical adhesive 64 may be cured by any suitable means such as in an oven.

Following interconnection of the series of foil segments 16, the foil assembly 50 may be spirally wound into a round shape and may then be attached to the top and bottom plates 14, 12 such as by using thermal adhesive 66 which may be cured by any suitable means such as in a convection oven. Such thermal adhesive 66 may be UV or visible-light curable adhesive such as an epoxy or an acrylate glue, if the top or bottom plates 14, 12 consist of UV or visible-light transparent materials such as ceramics. However, any suitable non-electrically conductive adhesive with high thermal conductivity may be utilized with the proper mechanical parameters. The endmost ones of the metal end contacts at extreme opposite ends of the foil assembly 50 may then be connected to respective ones of the top and bottom plates 14, 12 such that the top and bottom plates 14, 12 may serve as electrical contacts for the device to be powered. Such contacts may be functionally and structurally similar to the contacts of a conventional wristwatch battery. Sealing of the device is then performed in order to protect the thermoelectric generator 10 against humidity, chemicals, mechanical influence and any other debris which may adversely affect its operation.

In an alternative manufacturing process, it is contemplated that an elongate foil segment may be fabricated for a thermoelectric generator using roll-to-roll processing techniques in order to deposit an array of n-type and p-type thermoelectric legs onto at least one of the front and back substrate surfaces of substrate material. Metal bridges and end contacts may likewise be deposited on at least one of the front and back substrate surfaces using a similar roll-to-roll processing techniques. Likewise, fabrication of the connectors that may either include or omit metal contacts may also be fabricated during such roll-to-roll processing.

Referring to FIGS. 19-22 wherein the reference numerals in FIGS. 19-22 correspond to the reference numerals contained in the description below, shown in FIG. 19 is a perspective illustration of an embodiment of a thermoelectric generator 10 having an in-plane configuration wherein the longitudinal axis of the thermoelectric legs 26 of the thermoelectric generator 10 are oriented parallel to the surface of the substrate 20 upon which the thermoelectric legs 26 are formed. The embodiment shown in FIGS. 19-22 is the subject of U.S. application Ser. No. 12/605,370 entitled PLANAR THERMOELECTRIC GENERATOR filed on Oct. 25, 2009, the entire contents of which is expressly incorporated by reference herein in their entirety.

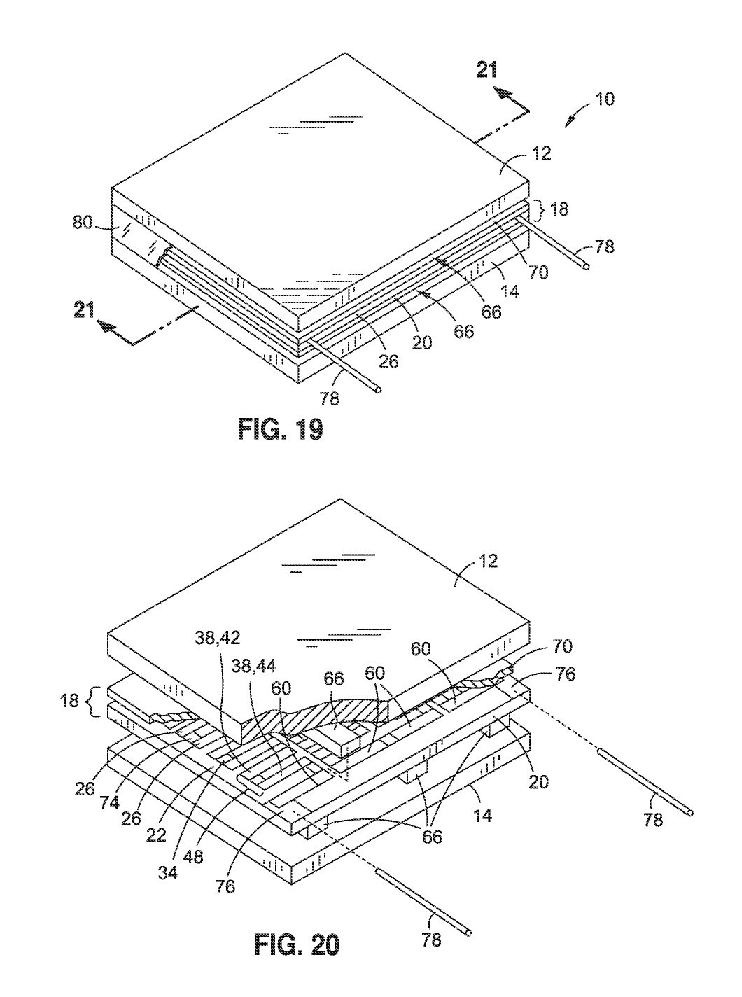

As can be seen in FIG. 20 and as will be described in greater detail below, the thermoelectric legs 26 are formed of alternating material types and are arranged in one or more rows 60. The thermoelectric legs 26 are oriented in non-parallel (e.g., perpendicular) relation to the axis of each row. Advantageously, the thermoelectric legs 26 form a meandering pattern on the substrate 20 which reduces internal stresses of the structure of the thin film which makes up the thermoelectric legs 26. Such internal stresses may result from different linear thermal expansion coefficients of the substrate 20 relative to the thermoelectric legs 26 at elevated temperatures during the fabrication process.

Advantageously, the meandering pattern of the thermoelectric legs 26 as illustrated in FIG. 20 minimizes the buildup of such internal stresses allowing for absorption of such stresses by the relatively short length of the thermoelectric legs 26 as well as by the constantly changing lateral orientation of the thermoelectric legs 26 of the meandering pattern. The net result of the meandering pattern is an increase in the mechanical stability and reliability of the foil assembly 18. In this regard, the arrangement of the thermoelectric generator 10 provides a degree of flexibility which may facilitate the mounting of the thermoelectric generator 10 to non-planar or curved surfaces.

A further advantage associated with the embodiments of the thermoelectric generator 10 as disclosed herein include the ability to tailor the geometry of the components that make up the thermoelectric generator 10 to the specific application for which the thermoelectric generator 10 is employed. For example, the length l, width w and thickness t₁ of the thermoelectric legs 26 may be configured to provide a relatively high thermal resistance in order to increase the temperature drop across the thermoelectric generator 10 (i.e., across the top and bottom plates 12, 14).

The in-plane thermoelectric generator 10 may be provided in an embodiment wherein the thermoelectric legs 26 have a generally large thickness in order to reduce the electrical resistance and thereby increase the power output. Because the voltage generated by the thermoelectric generator 10 is proportional to the temperature gradient acting across the series of thermocouples 48 formed by the adjacent pairs of thermoelectric legs 26, the ability to increase the temperature drop across the thermoelectric generator 10 results in an increase in the variety of different types of applications for which the thermoelectric generator 10 may be applied.

Referring still to FIG. 20, shown is the foil assembly 18 comprising the substrate 20 having an upper substrate surface 22 upon which a series of thermoelectric legs 26 are formed. The thermoelectric legs 26 are preferably formed of alternating dissimilar materials such as dissimilar semiconductor materials (i.e., n-type and p-type legs 42, 44). Alternatively, the alternating dissimilar materials that make up the thermoelectric legs 26 may be formed of semiconductor material 38 alternating with thermoelectric legs 26 formed of metallic material 34.

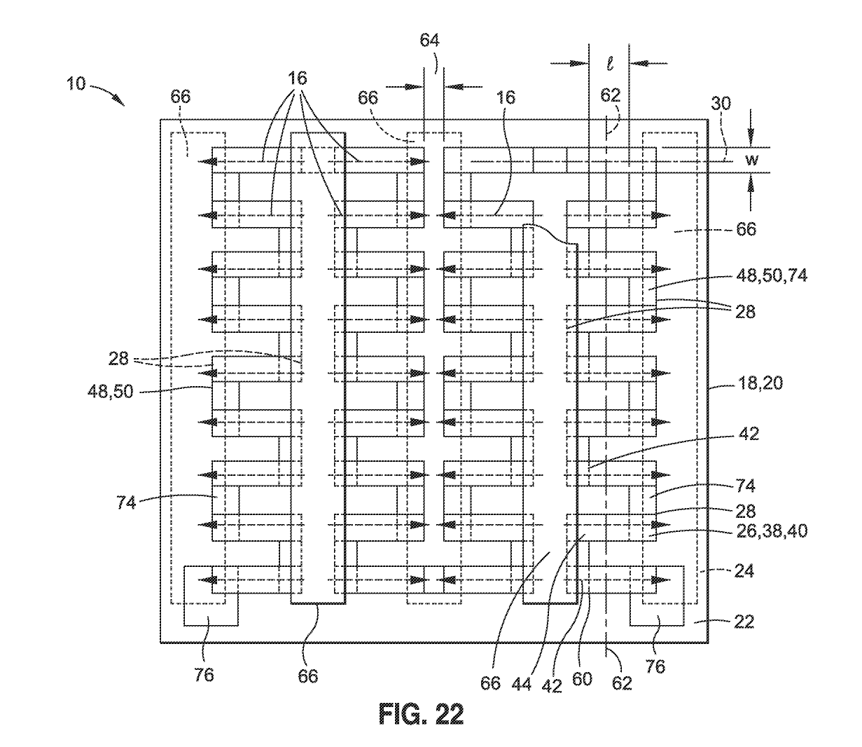

As can be seen in FIG. 20, the foil assembly 18 is located between the top and bottom plates 12, 14. The top and bottom plates 12, 14 are thermally connected to the thermoelectric legs 26 by means of one or more thermally conductive strips 66 which may be aligned with the opposing ends of the thermoelectric legs 26 in each row. The thermoelectric legs 26 may be electrically insulated from the top plate 12 by means of an electrically insulating layer 70 as illustrated in FIG. 22. The substrate 20 is preferably formed of an electrically insulating material such that the thermoelectric legs 26 are electrically insulated from the bottom plate. As can be seen, the bottom plate 14 is in thermal contact with the bottom surface of the substrate 20 by means of one or more of the thermally conductive strips 66. For example, the thermoelectric generator 10 shown in FIG. 20 includes three of the thermally conductive strips 66 in alignment with the leg ends 28 of the four rows 60 of thermoelectric legs 26. As best seen in FIG. 22, the middle thermally conductive strip 66 in contact with the bottom plate 14 serves as a thermal conduit for the middle two rows 60 of thermoelectric legs 26. The outer two thermally conductive strips 66 each serve as the thermal conduit for the outermost rows 60 of thermoelectric legs 26.

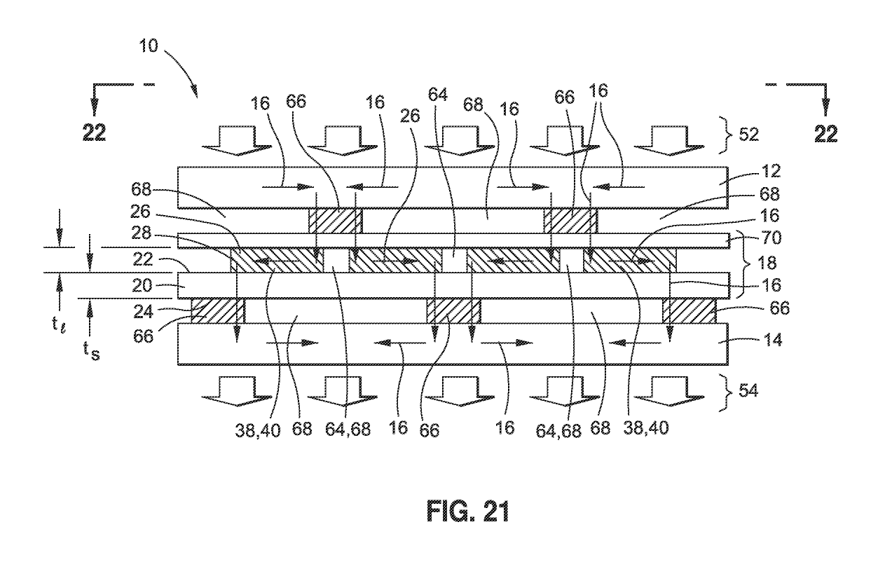

Referring to FIG. 21, shown are the locations of the thermally conductive strips 66 which can be seen as being generally aligned with opposite ends of the thermoelectric legs 26 in an adjacent pair of rows 60. The thermally conductive strips 66 are specifically arranged in order to facilitate the flow of heat from one heat couple plate through the foil assembly 18 and into the opposing top and bottom plate 12, 14. The thermally conductive strips 66 located adjacent the top plate 12 are arranged in alignment with the ends of the thermoelectric legs 26 of an adjacent pair of rows 60 while the thermally conductive strips 66 that are located adjacent the bottom plate 14 are aligned with the opposite leg ends 28 of the thermoelectric legs 26 in an adjacent pair of rows 60. Notably, the thermally conductive strips 66 are arranged in spaced relation to one another to form thermal gaps 68 which serve as areas of high thermal resistance causing a majority of the heat to flow through the thermoelectric legs 26. In this manner, the thermally conductive strips 66 are placed in thermal contact with the opposite leg ends 28 of each one of the thermoelectric legs 26 such that heat flows along the heat flow direction 16 indicated by the arrows in FIG. 21. In this regard, heat flows lengthwise through each one of the thermoelectric legs 26 in order to produce a voltage potential across the thermoelectric legs 26.

It should be noted that although FIG. 21 illustrates the top plate 12 as the heat source 52 and the bottom plate 14 as the heat sink 54 wherein heat flows from top to bottom, the thermoelectric generator 10 may operate in either direction of heat flow. For example, heat may flow from the bottom plate 14 toward the top plate 12 in a direction that is the reverse of that which is shown by the arrows in FIG. 21. In this regard, due to its symmetric configuration, the thermoelectric generator 10 generates electricity regardless of the direction of heat flow.

Referring to FIG. 22, shown is a top view of the thermoelectric generator 10 illustrating the direction of heat flow from the thermally conductive strips 66 through the thermoelectric legs 26. As can be seen, the thermoelectric legs 26 are arranged as a series of alternating thermoelectric legs 26 of dissimilar materials. For example, the thermoelectric legs 26 may alternate from different types of semiconductor materials such as n-type and p-type legs 42, 44. The substrate 20 is preferably formed of an electrically insulating material which preferably has a relatively low thermal conductivity. For example, in a preferred embodiment, the substrate 20 may be formed of polyimide material such as Kapton® commercially available from E. I. duPont de Nemours & Co., Inc. However, the substrate 20 may be formed of any suitable material having a relatively low thermal conductivity and which is preferably electrically insulating.

The substrate 20 may be provided in any suitable substrate thickness tₛ including, but not limited to, a substrate thickness tₛ in the range of from 5 microns to 100 microns. Preferably, the substrate 20 such as polyimide film is provided in a substrate thickness tₛ of 7.5 microns although 12.5 microns may also be a suitable substrate thickness tₛ. The substrate 20 is preferably formed of a material that is mechanically stable at the elevated temperatures associated with deposition of semiconductor films and with the annealing procedure. Furthermore, the substrate 20 is preferably a relatively thin material having dimensional stability and which is resistant against chemicals such as acids commonly used in the process for structuring the thermoelectric legs 26 following deposition thereof on the substrate 20.

Referring to FIG. 21, the thermoelectric legs 26 are preferably provided in a thickness which is compatible with the substrate 20 material as well as with the application for which the thermoelectric generator 10 is employed. For example, thermoelectric legs 26 may be formed of semiconductor material 38 in a leg thickness tₛ range of from 15 microns up to approximately 100 microns or more and, preferably, in a thickness tₛ of approximately 25 microns.

As indicated above, thermoelectric generators differ in their construction from heat sensors in that thermoelectric generators are preferably configured to have a high thermal resistance in order to maximize the temperature difference across the thermoelectric generator. Furthermore, the thermoelectric legs of an in-plane thermoelectric generator preferably have a relatively large leg thickness t₁ relative to the substrate thickness tₛ in order to minimize electrical resistance and thereby increase the power output. In this regard, the configuration of thermoelectric generators for producing electricity is generally opposite to the configuration of heat flux sensors. For example, heat flux sensors typically include thermoelectric legs of relatively small thickness in order to increase the response time of the heat flux sensor by minimizing the thermal capacity (i.e., thermal mass) of the thermoelectric legs.

Referring to FIGS. 20-22, the geometry of the thermoelectric legs 26 such as the leg length l may be sized to maximize power output. In this regard, the leg length l of the thermoelectric legs 26 may be in the range of from 50 microns to 500 microns although the leg length l may be provided in any range. As indicated earlier, the thermoelectric legs 26 are preferably provided in a relatively short length in order to increase the power output. However, the selection of the leg length may be based upon the thermal resistance of a relatively short leg length in consideration of the temperature drop across the thermoelectric leg 26 as a result of other resistances in series and/or parallel with the thermoelectric leg 26.

Advantageously, the in-plane configuration of the thermoelectric generator 10 as disclosed herein facilitates the implementation of a relatively wide range of leg lengths as compared to a cross-plane configuration of a thermoelectric generator wherein adjustability of the leg length is limited in the ability to build up the thickness (i.e., leg length) along a direction normal to the substrate 20. The ability to vary the leg lengths facilitates tailoring the performance of the thermoelectric generator 10 to a given thermal environment. For example, for applications with lower available heat flow and reduced temperature gradient such as body heat applications, the thermoelectric legs 26 may be provided in a relatively long length in order to achieve higher thermal resistances. In addition, the thermoelectric legs 26 may be provided in any suitable width w such as widths in the range of from about 10 microns up to about 500 microns.

As was earlier mentioned, internal stresses in the thermoelectric legs 26 may be minimized by frequently changing the lateral orientation of the thermoelectric legs 26 and by minimizing the leg lengths. In this regard, the thickness of the thermoelectric legs 26 may be sized in relation to the leg length. The leg length may be sized in relation to the substrate thickness tₛ in consideration of internal stresses in the thermoelectric legs 26 and to increase the flexibility or bendability of the foil assembly 18. The enhanced flexibility may improve thermal contact of the thermoelectric generator 10 to a curved surface of a heat source 52 or heat sink 54. In this regard, the leg thickness t₁ of the thermoelectric legs 26 may be provided in a specific ratio relative to the substrate thickness L. For example, the leg thickness t₁ may be provided in a multiple of from 1 to about 10 times the substrate thickness tₛ and, more preferably, the thermoelectric legs 26 may be provided in a leg thickness t₁ that is about 2 to 4 times the thickness of the substrate 20. However, the thermoelectric legs 26 may be provided in any leg thickness t₁ relative to the substrate thickness L.

For configurations of the thermoelectric generator 10 wherein the thermoelectric legs 26 are formed of metallic material 34, such metal legs 36 may be provided in a generally reduced thickness relative to thermoelectric legs 26 formed of semiconductor material 38. For example, metal legs 36 may have a leg thickness t₁ from about 0.5 microns to about 5 microns although the metal legs 36 may be provided in any thickness. Configurations of the thermoelectric generator 10 implementing the use of metal legs 36 are illustrated in FIGS. 25A-25G and FIGS. 26A-26F as described in greater detail below.

Referring still to FIGS. 19-20, shown are the thermally conductive strips 66 which may be mounted on opposite sides of the substrate 20 for thermally connecting the top and bottom plates 12, 14 to the thermoelectric legs 26. Although shown as elongate strips extending along a substantial width of the thermoelectric generator, it is also contemplated that the thermally conductive strips 66 may be configured as a plurality of segments disposed at spaced relation to one another and thermally connecting the ends of the thermoelectric legs 26 to the top plate 12 and bottom plates as illustrated in FIG. 21. Even further, it is contemplated that the thermally conductive strips 66 may be formed as discrete or localized deposits of thermally conductive material in order to thermally connect the ends of the thermoelectric legs 26 to the top and bottom plates 12, 14. In this regard, the thermally conductive strips 66, segments or deposits may be configured in a wide variety of configurations and in a wide range of materials. For example, the thermally conductive strips 66 may be configured as strips of thermally conductive adhesive or as strips of material similar to the material from which the thermally conductive top and bottom plates 12, 14 are formed.

In this regard, the top and bottom plates 12, 14 may be formed of any suitable material including, but not limited to, metal material or ceramic material such as aluminum oxide, aluminum nitride, beryllium oxide and other suitable material having a high thermal conductivity. The thermally conductive strips 66 may be integrated into the top and/or bottom plates 12, 14. For example, a ceramic heat couple plate (i.e., top or bottom plate 12, 14) may be integrally formed with the thermally conductive strips 66 on one side of the plate. The thermally conductive strips 66 may be formed by appropriate fabrication of the top and bottom plates 12, 14 and may include dicing, laser ablation, and micro-stamping (i.e., pressing) which may be performed prior to sintering of the ceramic material. In a further embodiment, one or both of the top and bottom plates 12, 14 may be formed of ceramics with a metal pattern being formed on one side using physical vapor deposition processes (i.e., sputtering, evaporation, electron beam deposition) or electro deposition which may be followed by photolithographic structuring.

The top and bottom plates 12, 14 may optionally be formed as a stack of metal foils and which may have the thermally conductive strips 66 integrated therewithin. In this regard, metal foils may be formed into the top and bottom plates 12, 14 by pressing, folding, creasing, stamping, laser ablation or by soldering the surfaces of the top and bottom plates 12, 14 with a partially covered photolithographic mask in order to make gutter-shaped depressions for the thermally conductive strips 66. The top and bottom plates 12, 14 may be formed from silicon plates fabricated using silicon wafers wherein the thermally conductive strips 66 may be formed by micro-machining (i.e., etching) of the thermally conductive strips 66 on one side of the top and bottom plates 12, 14. The top and bottom plates 12, 14 may also be formed from metal foils wherein a pattern of thermally conductive adhesive may be formed on the metal foils by screen printing or by pin transfer. Alternatively electrically conductive top and bottom plates 12, 14 or electrically conductive layers on one or both of electrically insulated top and bottom plates 12, 14 may be used as metal contacts for the thermoelectric generator 10 if the metal contacts 76 of the foil assembly 18 are electrically connected to such electrically conductive layers.

Referring still to FIGS. 21-22, it is further contemplated that the top and bottom plates 12, 14 may be integrated into a heat exchanger or heat pipes or other specific profiles to improve heat exchange or to couple in heat from a heat source 52 or couple heat out to a heat sink 54. In this regard, one or more of the top and bottom plates 12, 14 may be integrated into a heat exchanger as a unitary structure wherein the heat exchanger is attached directly to or is integrated with the top and bottom plates 12, 14. Such an arrangement may result in reduced thermal resistance across the thermal connection between the heat exchanger and the top and bottom plates 12, 14. Furthermore, such arrangement may increase the temperature gradient across the thermoelectric generator 10 and may reduce production costs. The thermally conductive top and bottom plates 12, 14 may also be attached or bonded to the foil assembly 18 by means of the thermally conductive strips 66 using a suitable thermally conductive adhesive. Such thermally conductive adhesive may be room temperature curable or may be curable by exposure to heat and/or ultraviolet radiation.

Soldering may also be employed in order to attach the top and/or bottom plates to the thermally conductive strips 66 and/or to the foil assembly 18. For example, the top and/or bottom plates 12, 14 may include metalized strips such as in a stripe pattern to allow for soldering of the top and/or bottom plates 12, 14 to the substrate 20 and/or the electrically insulating layer 70 (e.g., photo resist layer). Furthermore, the solder can itself be used as the thermally conductive strips 66 to connect the top and/or bottom plates to the foil assembly 18. In this regard, thin metal strips preferably made of nickel may be deposited on the lower substrate surface and/or on a top surface of the electrically insulating layer 70 opposite to the thermally conductive strips 66. Such metal strips may be deposed by any suitable means including, but not limited to, sputtering and photolithographic structuring (e.g., a lift-off technique or positive resist followed by etching) in order to obtain a solderable surface and to facilitate assembly of the top and bottom plates 12, 14 and thermally conductive strips 66 by soldering.

Referring still to FIGS. 21-22, the thermoelectric legs 26 in the rows 60 are preferably electrically connected in series to the thermoelectric legs 26 of adjacent one of the rows 60. As shown in FIG. 21, the thermoelectric generator 10 may include at least one electrically insulating layer 70 such as a strip, segment or sheet of electrically insulating material which may be interposed between the thermally conductive strips 66 and the adjacent thermoelectric legs 26. The leg ends 28 of the thermoelectric legs 26 in each row 60 are spaced apart from the leg ends 28 of the thermoelectric legs 26 in an adjacent row 60 to define a row gap 62. As can be seen in FIG. 21, the thermally conductive strips 66 are preferably aligned with the row 60 gaps such that a single one of the thermally conductive strips 66 facilitates flow of heat into or out of the thermoelectric leg 26 on each side of the row gap 62.

Additional modifications and improvements of the present disclosure may also be apparent to those of ordinary skill in the art. Thus, the particular combination of parts described and illustrated herein is intended to represent only certain embodiments of the present disclosure, and is not intended to serve as limitations of alternative devices within the spirit and scope of the disclosure.

What is claimed is:

1. A wearable thermoelectric generator system, comprising:
a thermoelectric generator;
a heat collector configured to be placed in contact with a skin surface of a wearer;
a heat exchanger being exposable to ambient air;
the thermoelectric generator being disposed between the heat collector and the heat exchanger and being electrically connected to a load;
the load being packaged separately from the thermoelectric generator; and
the system being configured in at least one of a band configuration and a patch configuration.

2. The system of claim 1 further comprising:
an insulation layer interposed between the heat collector and the heat exchanger; and
the insulation layer being disposed against a side of the thermoelectric generator.

3. The system of claim 1 wherein the band configuration includes:
an outer material layer; and
a thermally insulating middle layer mounted on a side of the outer material layer such that the thermally insulating middle layer is configured to contact the skin surface of a wearer.

4. The system of claim 3 wherein the band configuration further includes:
an inner material layer mounted to the thermally insulating middle layer; and
the thermally insulating middle layer being disposed between the inner material layer and the outer material layer.

5. The system of claim 4 wherein:
at least one of the inner material layer and the outer material layer is formed of a flexible material configured to conform to a body contour of the wearer.

6. The system of claim 5 wherein:
the load comprises an electronics module mounted to at least one of the inner and outer material layer.

7. The system of claim 1 wherein:
the patch configuration comprises a back pack embodiment including at least one of a flexible material and a rigid material configured to be placed in thermal contact with the wearer's skin.

8. The system of claim 1 wherein:
the wearer's skin comprises a heat source;
the ambient air comprises a heat sink;
the thermoelectric generator having a pair of heat couple plates and at least one thermocouple including a thermoelectrically active zone having a thermal resistance and, one of the heat couple plates being in contact with the thermocouple and the heat collector, a remaining one of the heat couple plates being in contact with the thermocouple and the heat exchanger; and
the thermal resistance of the thermoelectrically active zone being substantially equivalent to a sum of the thermal resistances in series of at least one the heat source, the heat sink, and the heat couple plates.

9. The system of claim 8 wherein:
the thermal resistance of the thermoelectrically active zone is within approximately 50 percent of the sum of the thermal resistances in series of at least one of the heat sink, the heat source, and the heat couple plates.

10. The system of claim 8 wherein:
the thermoelectric generator is configured to generate electricity when the function of the heat source and the heat sink are reversed such that the heat source functions as the heat sink, and the heat sink functions as the heat source.

11. The system of claim 8 wherein:
the heat source further comprises at least one of the following: a body of a non-human animal, an inanimate object; and
the heat sink further comprises at least one of the following: a fluid including a gas or a liquid, solid matter.

12. The system of claim 1 wherein:
the thermoelectric generator has an electrical resistance and is connectable to the load having an electrical resistance; and
the thermoelectric generator being configurable such that the electrical resistance of the thermoelectric generator is substantially equivalent to the electrical resistance of the load.

13. The system of claim 1 wherein the thermoelectric generator is incorporated into at least one of the following configurations:
a wrist band, an arm band, a leg band, an ankle band, a foot band, foot wear, head wear, an article of clothing, a patch, an appliqué, a layer, a strip, an article configured to be carried or held, a structural article, a non-structural article, a system, a subsystem, an apparatus, an assembly, a vehicle, a building, a structure.

14. The system of claim 1 wherein the thermoelectric generator has at least one of the following configurations:
an in-plane configuration; and
a cross-plane configuration.

15. A wearable thermoelectric generator system, comprising:
a thermoelectric generator;
a heat collector configured to be placed in contact with a skin surface of a wearer;
a heat exchanger being exposable to ambient air;
the thermoelectric generator being disposed between the heat collector and the heat exchanger and being electrically connected to a load, the load being packaged separately from the thermoelectric generator;
an insulation layer interposed between the heat collector and the heat exchanger and being disposed against the sides of the thermoelectric generator; and
the system being configured in at least one of a band configuration and patch configuration.

16. The system of claim 15 wherein the band configuration includes:
an outer material layer; and
a thermally insulating middle layer mounted on a side of the outer material layer such that the thermally insulating middle layer is configured to contact the skin surface of a wearer.

17. The system of claim 16 wherein the band configuration further includes:
an inner material layer mounted to the thermally insulating middle layer; and
the thermally insulating middle layer being disposed between the inner material layer and the outer material layer.

18. The system of claim 17 wherein:
at least one of the inner material layer and the outer material layer is formed of a flexible material configured to conform to a body contour of the wearer.

19. The system of claim 15 wherein the thermoelectric generator is incorporated into at least one of the following configurations:
a wrist band, an arm band, a leg band, an ankle band, a foot band, foot wear, head wear, an article of clothing, an appliqué, a layer, a strip, and an article configured to be carried.

20. The system of claim 15 wherein:
the wearer's skin comprises a heat source;
the ambient air comprises a heat sink; and
the thermoelectric generator being configured to generate electricity when the function of the heat source and the heat sink are reversed such that the heat source functions as the heat sink and the heat sink functions as the heat source.
